(19) United States
(12) Patent Application Publication
(10) Pub. No.: US 2025/0393377 A1
(43) Pub. Date: Dec. 25, 2025

(54) DISPLAY DEVICE

(71) Applicant: LG Display Co., Ltd., Seoul (KR)

(72) Inventors: Myeongchan KIM, Paju-si (KR); Wonki PARK, Paju-si (KR); Younsung NA, Paju-si (KR); Jaebin SONG, Paju-si (KR)

(73) Assignee: LG Display Co., Ltd., Seoul (KR)

(21) Appl. No.: 19/239,335

(22) Filed: Jun. 16, 2025

(30) Foreign Application Priority Data
Jun. 20, 2024 (KR) 10-2024-0080314

(51) Int. Cl. H10H 29/855; H01L 25/16; H10H 29/37; H10H 29/80

(52) U.S. Cl. CPC H10H 29/855; H01L 25/167; H10H 29/37; H10H 29/8323

(57) ABSTRACT

The present application relates to a display device. A display device according to an exemplary embodiment of the present disclosure includes a substrate, at least one driving chip disposed on the substrate, a bank disposed on the driving chip, a first electrode disposed on the bank and electrically connected to the at least one driving chip, a light-emitting element disposed on the first electrode, and first and second sidewall diffusion layers laminated around the bank and the light-emitting element, wherein the first sidewall diffusion layer includes a plurality of first fine particles, and the second sidewall diffusion layer includes a plurality of second fine particles having a refractive index different from that of the plurality of first fine particles.

### CROSS-REFERENCE TO RELATED APPLICATION

This application claims priority from Republic of Korea Patent Application No. 10-2024-0080314 filed on Jun. 20, 2024, in the Korean Intellectual Property Office, which is incorporated by reference in its entirety.

### BACKGROUND

### Technical Field

The present disclosure relates to a display device, and more specifically, for example, without limitation, to a display device having an improved external light reflection prevention characteristic as well as an improved light extraction efficiency.

### Description of the Related Art

Display devices are applied to various electronic devices such as TVs, mobile phones, laptops, and tablets.

The display device includes organic light-emitting display (OLED) device having self-luminous property, and liquid crystal display (LCD) device requiring a separate light source.

Recently, a display device including a light-emitting diode (LED) is attracting attention as next-generation display device. Since the light-emitting diode is not made of organic materials but inorganic materials, the display device including a light-emitting diode lights up faster than the liquid crystal display device or the organic light-emitting display device, has excellent luminous efficiency, and can display with high luminance.

The description provided in the discussion of the related art section should not be assumed to be prior art merely because it is mentioned in or associated with that section. The discussion of the related art section may include information that describes one or more aspects of the subject technology, and the description in this section does not limit the present application.

### BRIEF SUMMARY

The present disclosure relates to a display device, particularly a micro-LED display, that improves light extraction efficiency and reduces external light reflection using a dual-layer sidewall diffusion structure. The sidewall includes two laminated layers composed of fine particles with differing refractive indices, which enhances optical performance and allows for wider black matrix openings while reducing or minimizing visual artifacts. The display also integrates micro driver circuits directly on the substrate, with each driver capable of controlling multiple light-emitting elements, supporting compact layouts, reduced power consumption, and high-resolution output.

To address manufacturing challenges, each subpixel incorporates redundant light-emitting elements, enabling selection of the most functional unit after transfer. Stress is mitigated in bendable regions through the use of ductile materials and patterned link lines, while brittle inorganic layers are omitted from these areas to improve mechanical durability. A transparent common electrode facilitates efficient cathode routing and enhances light emission, and the pixel layout accommodates flexible subpixel arrangements and redundancy to improve reliability and yield.

Various embodiments of the present disclosure provides a display device having an improved external light reflection prevention characteristic as well as an improved light extraction efficiency.

The present disclosure may have other technical benefits besides the aforementioned one, which are clearly recognizable to a person skilled in the art from the description below.

A display device according to various embodiments of the present disclosure may include at least one driving chip disposed on a substrate, a bank disposed on the driving chip, a first electrode disposed on the bank and electrically connected to the at least one driving chip, a light-emitting element disposed on the first electrode, and first sidewall diffusion layer and second sidewall diffusion layer laminated around the bank and the light-emitting element. In this regard, the first sidewall diffusion layer may include a plurality of first fine particles, and the second sidewall diffusion layer may include a plurality of second fine particles having a refractive index different from a refractive index of the plurality of first fine particles.

In another aspect, a display device according to various embodiments of the present disclosure may include at least one light-emitting element disposed on a substrate, a sidewall diffusion layer covering a side surface of the at least one light-emitting element, and a transparent electrode disposed on the at least one light-emitting element and the sidewall diffusion layer. In this regard, the sidewall diffusion layer may include a first sidewall diffusion layer having a plurality of first fine particles dispersed therein and a second sidewall diffusion layer having a plurality of second fine particles dispersed therein, and the plurality of first fine particles and the plurality of second fine particles may have refractive indices different from each other.

In yet another aspect, a display device according to various embodiments of the present disclosure may include a driving chip comprising a plurality of driving circuits to drive at least one of a plurality of light-emitting elements; a bank disposed on the driving chip; first and second sidewall diffusion layers laminated around the bank and the light-emitting element, in which the first sidewall diffusion layer includes a plurality of first fine particles, and a refractive index of a plurality of second fine particles included in the second sidewall diffusion layer is lower than a refractive index of the plurality of first fine particles.

According to an exemplary embodiment of the present disclosure, the sidewall diffusion layer covering the side surface of the light-emitting element includes fine particles, so that the extraction efficiency of light emitted from the light-emitting element can be improved. By improving the light extraction efficiency of the light-emitting element, it is possible to provide a display device capable of reducing power consumption.

In addition, according to an exemplary embodiment of the present disclosure, the sidewall diffusion layer is disposed on the side surface of a light-emitting element, and is configured by laminating the first sidewall diffusion layer including the first fine particles having a high refractive index and the second sidewall diffusion layer including the second fine particles having the refractive index lower than that of the first fine particles, so that the non-polarized scattering characteristic of the sidewall diffusion layer can be reduced, and thus the external light reflection prevention characteristic of the display device can be improved.

Additionally, according to an exemplary embodiment of the present disclosure, as the non-polarized scattering of the sidewall diffusion layer is alleviated or reduced, the size of the opening of the black matrix can be increased, and thus, stain defects (e.g., stamp mura) caused by asymmetry and dispersion of the gap between the edge of the light-emitting element and the edge of the opening of the black matrix can be alleviated.

The present disclosure can provide other effects besides the ones described above, which are clearly recognizable to a person skilled in the art from the claims.

It is to be understood that both the foregoing general description and the following detailed description of the present disclosure are exemplary and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is an exploded perspective view of a display device according to an exemplary embodiment of the present disclosure.

FIG. 2 is a plan view of a display device according to an exemplary embodiment of the present disclosure.

FIG. 3 is an enlarged view of a display device according to an exemplary embodiment of the present disclosure.

FIG. 4 is a diagram showing a circuit structure according to an exemplary embodiment of the present disclosure.

FIG. 5 is a plan view of a display device according to an exemplary embodiment of the present disclosure.

FIG. 6 is a plan view of a display device according to an exemplary embodiment of the present disclosure.

FIG. 7 is a plan view of a display device according to an exemplary embodiment of the present disclosure.

FIG. 8 is a cross-sectional view of a display device according to an exemplary embodiment of the present disclosure.

FIG. 9 is a cross-sectional view of a display device according to an exemplary embodiment of the present disclosure.

FIGS. 10 to 13 are views illustrating devices to which display devices according to exemplary embodiments of the present disclosure are applied.

FIG. 14 is a plan view of a display panel according to an exemplary embodiment of the present disclosure.

FIG. 15 is a plan view showing an area where one of the plurality of driving chips of FIG. 14 is disposed.

FIG. 16 is a diagram illustrating touch operation of a display device according to an exemplary embodiment of the present disclosure.

FIG. 17 is a diagram illustrating, by way of example, a signal waveform diagram when driving a display device according to an exemplary embodiment of the present disclosure.

FIG. 18 is a cross-sectional view taken along line XVIII-XVIII of FIG. 14.

FIG. 19 is an enlarged plan view of a display area with a plurality of pixels included therein of a display device according to an exemplary embodiment of the present disclosure.

FIG. 20 is a cross-sectional view taken along line XX-XX of FIG. 19.

FIG. 21 is a cross-sectional view taken along line XXI-XXI of FIG. 19.

FIG. 22 is a cross-sectional view of a display device according to an exemplary embodiment of the present disclosure.

FIG. 23 is a cross-sectional view of a display device according to an exemplary embodiment of the present disclosure.

FIG. 24 is a cross-sectional view of a display device according to an exemplary embodiment of the present disclosure.

FIG. 25 is a cross-sectional view of a display device according to an exemplary embodiment of the present disclosure.

FIG. 26 is a cross-sectional view of a display device according to an exemplary embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTIONS

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure, and a method of achieving the advantages and features will become apparent when referring to the following exemplary embodiments described later in detail together with the accompanying drawings. However, the present disclosure is not limited to the exemplary embodiments as disclosed below, but may be embodied in various different forms. Thus, these embodiments are set forth only to make the present disclosure complete, and to completely inform the scope of the present disclosure to those of ordinary skill in the technical field to which the present disclosure belongs. Further, the present disclosure is only defined by scopes of claims.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Throughout the detailed description, like reference numerals refer to like components. Further, in describing the present disclosure, if it is determined that a detailed description of a related known technology may unnecessarily obscure the gist of the present disclosure, the detailed description thereof will be omitted. It will be further understood that the terms “comprise,” “comprising,” “include,” and “including” “contain,” “constitute,” “make up of,” “formed of,” when used in the present disclosure, specify the presence of the stated features, integers, operations, elements, and/or components, but do not preclude the presence or addition of one or more other features, integers, operations, elements, components, and/or portions thereof. When using an expression in a singular form to describe a component, it can include a meaning of a plural form unless explicitly stated to the contrary.

It should be noted that any component will be construed as including a tolerance or error range, even if there is no explicit description thereof. Any implementation described herein as an “example” is not necessarily to be construed as preferred or advantageous over other implementations.

In describing a position relationship between two elements, for example, when the position relationship is described using “on,” “over” “upon,” “above,” “below,” and “next to,” one or more other elements may be interposed between the two elements unless “just,” “directly,” or “close” is used. For example, where an element or layer is disposed “on” another element or layer, a third layer or element may be interposed therebetween.

In describing a temporal relationship, for example, when the temporal order is described as “after,” “subsequent,” “next,” and “before,” the case which is not continuous may also be included unless “just” or “directly” is used.

It will be understood that, although the terms “first,” “second,” “A,” “B,” “(A),” or “(B),” etc., may be used herein to describe various elements, these elements should not be limited by these terms. These terms are only used to distinguish one element from another element. So, a first element referred to in the following description may represent a second element, and, similarly, a second element could be termed a first element, without departing from the scope of the technical idea of the present disclosure.

In describing components herein, terms such as first, second, A, B, (a), or (b) may be used. These terms are only intended to distinguish one component from another, and do not limit the nature, order, sequence, or number of the components.

When a component is described as being “connected to,” “coupled to,” “in contact with,” or “attached to” another component, such component may be directly connected to, coupled to, contact with, or attached to the other component, and, however, it should be understood that they may be indirectly connected to, coupled to, contact with, or attached to each other with still another component interposed therebetween, unless explicitly stated to the contrary.

When a component or layer is described as “being in contact with,” or “overlapping with” another component or layer, such component or layer may directly be in contact with or overlap with the other component or layer, and, however, it should be understood that they may also indirectly be in contact with or overlap with each other with still another component or layer interposed between, unless explicitly stated to the contrary.

To elaborate, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The expression “at least one” should be understood to include any combination of one or more of the associated components. For example, the meaning of “at least one of the first, second, and third components” may include not only the first, second, or third component, but also any combination of two or more of the first, second, and third components.

The terms “first direction,” “second direction,” “third direction,” “X-axis direction,” “Y-axis direction,” and “Z-axis direction” should not be interpreted as merely geometric relationships in which the relationship between them is perpendicular to each other, but may mean a wider directionality within the range in which the configuration of the present disclosure can act functionally.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

The individual features of the various embodiments of the present disclosure may be coupled or combined with each other in part or in whole to be interconnected and operated in a variety of technical ways, and each embodiment may be implemented independently of each other or implemented together in an associative relationship.

Hereinafter, various embodiments of the present disclosure will be described in detail with reference to the accompanying drawings. The scales of the components shown in the drawings have different scales from the actual ones for convenience of explanation, and thus are not limited to the scales shown in the drawings.

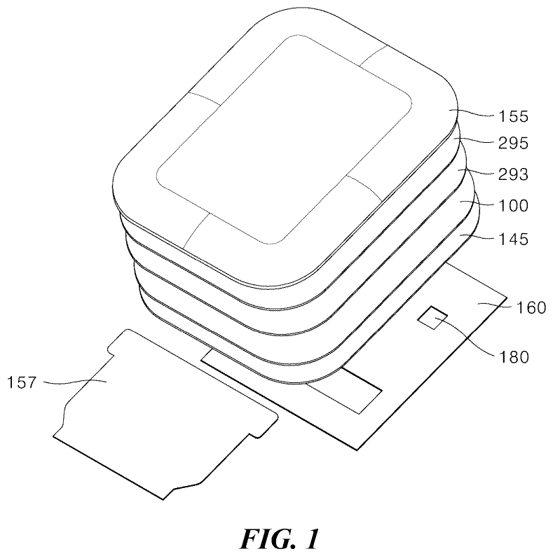

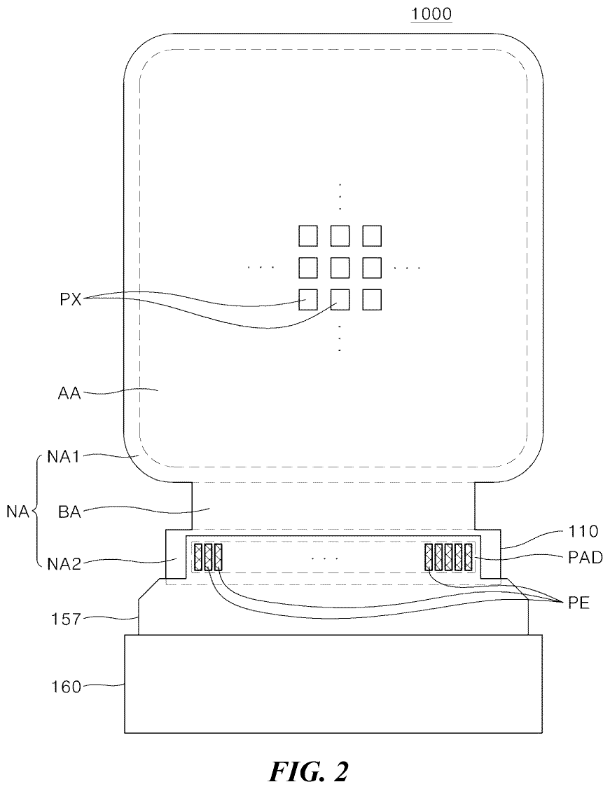

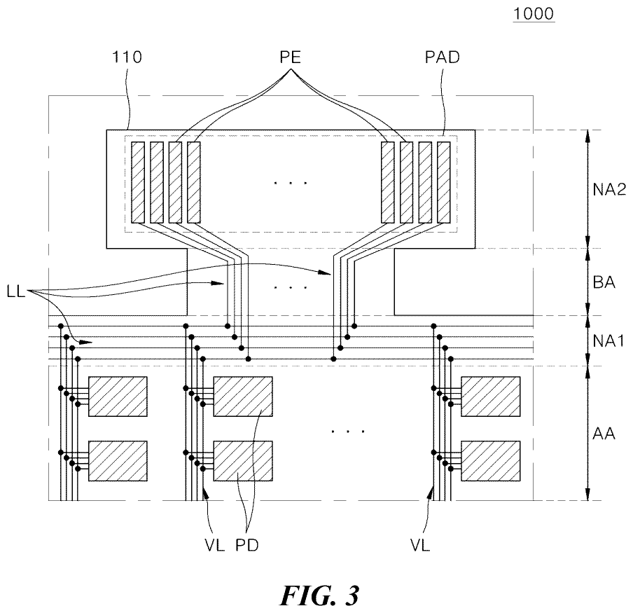

FIG. 1 is a perspective view showing a display device according to an exemplary embodiment of the present disclosure. FIG. 2 is a plan view of a display device according to an exemplary embodiment of the present disclosure. FIG. 3 is an enlarged view of a display device according to an exemplary embodiment of the present disclosure.

Referring to FIGS. 1 to 3, a display device 1000 according to an exemplary embodiment of the present disclosure may include a display panel 100, a polarizing layer 293, an adhesive layer 295, a cover member 155, a support substrate 145, a flexible circuit board 157, and a printed circuit board 160.

For example, the display device 1000 may include a substrate 110. The substrate 110 may be a member that supports other components of the display device 1000. The substrate 110 may be made of an insulating material. For example, the substrate 110 may be made of glass or resin. Alternatively, the substrate 110 may be made of a material having flexibility. For example, the substrate 110 may be made of a plastic material having flexibility, such as polyimide (PI). However, the embodiments of the present disclosure are not limited thereto. For example, the substrate 110 may be made of a flexible polymer film. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS), which is only an example and is not necessarily limited thereto.

The display panel 100 can implement information, video, and/or images to be provided to a user. For example, the display panel 100 may include a display area AA and a non-display area NA. For example, the substrate 110 may include the display area AA and the non-display area NA. The distinction between the display area AA and non-display area NA are applied not only to the substrate 110 but also be applied to the entire display device 1000.

The display area AA may be an area where an image is displayed. The display area AA may include a plurality of pixels PX. Each of the plurality of pixels PX may be constituted with a plurality of sub-pixels. At each of the plurality of sub-pixels a plurality of light-emitting elements may be disposed. The plurality of light-emitting elements may be configured differently depending on the kinds of display device 1000. For example, in a case where the display device 1000 is an inorganic light-emitting display device, the light-emitting element may be a light-emitting diode (LED), a micro light-emitting diode (micro LED), or a mini light-emitting diode (mini LED). However, the embodiments of the present disclosure are not limited thereto.

The non-display area NA may be an area where an image is not displayed. In the non-display area NAA, various wirings and circuits for driving a plurality of pixels PX in the display area AA may be disposed. For example, various wires and driving circuits may be mounted in the non-display area NA, and a pad part PAD to which integrated circuits and printed circuits are connected may be disposed in the non-display area NA. However, the embodiments of the present disclosure are not limited thereto.

For example, the driving circuit may be a circuit for driving the display panel 100. For example, the driving circuit may include, but is not limited to, a data driving circuit and/or a gate driving circuit. However, the embodiments of the present disclosure are not limited thereto. For example, the driving circuit may further include other circuit components. In the non-display area NA, there may be disposed wirings through which control signals for controlling the driving circuits are supplied. For example, the control signal may include various timing signals including synchronization signals, an input data enable signal, and a clock signal. However, the embodiments of the present disclosure are not limited thereto. The control signal may be received through the pad part PAD. For example, the control signal may be supplied to the substrate 110 from the outside of the substrate 110 through the pad part PAD. For example, in the non-display area NA, there may be disposed link lines LL for transmitting a signal. For example, driving components such as the flexible circuit board 157 and the printed circuit board 160 may be connected to the pad part PAD.

According to the present disclosure, the non-display area NA may include a first non-display area NA1, a bending area BA, and a second non-display area NA2. For example, the bending area BA can be disposed between the first non-display area NDA1 and the second non-display area NDA2. For example, the first non-display area NA1 may be an area surrounding at least a portion of the display area AA. The bending area BA may be an area which is bendable and extends from at least one of a plurality of sides of the first non-display area NA1. The second non-display area NA2 may be an area which extends from the bending area BA, and in which the pad part PAD may be disposed. For example, the bending area BA may be in a bent state, and the remaining area of the substrate 110 except the bending area BA may be in a flat state. In this case, as the bending area BA is bent, the second non-display area NA2 can be located on the rear surface of the display area AA. However, the embodiments of the present disclosure are not limited thereto.

The display area AA of the substrate 110 or the display device 1000 may be configured in various shapes depending on the designs of the display device 1000. For example, the display area AA may be configured in a rectangular shape with four rounded corners. However, the embodiments of the present disclosure are not limited thereto. For another example, the display area AA may be configured in a rectangular shape with four right-angled corners, a circular shape, or the like. However, the embodiments of the present disclosure are not limited thereto.

According to the present disclosure, the width of the second non-display area NA2 in which a plurality of pad electrodes PE are disposed may be greater than the width of the bending area BA in which only the plurality of link lines LL are disposed. Additionally, the width of the display area AA in which the plurality of sub-pixels are disposed may be greater than the width of the bending area BA in which only the plurality of link lines LL are disposed. Although the width of the bending area BA is depicted in the drawing as being smaller than the widths of other areas of the substrate 110, the shape of the substrate 110 including such bending area BA is only an example, and the embodiments of the present disclosure are not limited thereto.

Referring to FIG. 3, a plurality of pixel driving circuits PD may be disposed in the display area AA. The plurality of pixel driving circuits PD may be circuits for driving light-emitting elements of a plurality of sub-pixels. Each of the plurality of pixel driving circuits PD may include a plurality of transistors including a driving transistor, a storage capacitor and the like, and may control the light-emitting operation of the plurality of light-emitting elements by supplying a control signal, power, and a driving current to the light-emitting elements of the plurality of sub-pixels. For example, a pixel driving circuit PD may include a power line and a signal line for controlling the on/off and/or light-emitting time of a light-emitting element. For example, the plurality of pixel driving circuits PD may be driving chips manufactured on a semiconductor substrate using a metal-oxide-silicon field effect transistor (MOSFET) manufacturing process. However, the embodiments of the present disclosure are not limited thereto. The driving chip may include a plurality of pixel driving circuits PD, and may drive a plurality of sub-pixels. For example, the plurality of pixel driving circuits PD may belong to a micro driver, which is a kind of a driving chip having a size of several tens of μm to several hundreds of μm. However, the embodiments of the present disclosure are not limited thereto.

Referring to FIG. 1 together, the flexible circuit board 157 and the printed circuit board 160 may be disposed at the lower side of the display panel 100. The flexible circuit board 157 and the printed circuit board 160 may be disposed at least on one edge of the display panel 100. However, the embodiments of the present disclosure are not limited thereto. One side of the flexible circuit board 157 may be attached to the display panel 100, and the other side thereof may be attached to the printed circuit board 160. For example, the flexible circuit board 157 may be disposed between the display panel 100 and the printed circuit board 160. However, the embodiments of the present disclosure are not limited thereto. The flexible circuit board 157 may be made of a flexible film. However, the embodiments of the present disclosure are not limited thereto.

In the second non-display area NA2, the pad part PAD may be disposed which includes the plurality of pad electrodes PE. A driving component including one or more flexible circuit boards (or flexible films) 157 and the printed circuit boards 160 may be attached or bonded to the pad part PAD which includes the plurality of pad electrodes PE. The plurality of pad electrodes PE of the pad part PAD may be electrically connected to one or more flexible circuit boards (or flexible films) 157 to transmit various signals or power from the printed circuit board 160 and the flexible circuit board (or flexible film) 157 to the plurality of pixel driving circuits PD in the display area AA.

The flexible circuit board (or flexible film) 157 may be a film in which various components are disposed on a flexible base film. For example, a driving IC such as a gate driver IC or a data driver IC may be disposed on the flexible circuit board (or flexible film) 157. However, the embodiments of the present disclosure are not limited thereto. For example, at least one of a gate driver IC or a data driver IC may be disposed in the display area AA of the display panel 100. For example, at least one of a gate driver IC or a data driver IC may be configured not to overlap with sub-pixels, or configured to overlap with one or more, or all, of the sub-pixels, or at least respective one or more portions of one or more sub-pixels. However, the embodiments of the present disclosure are not limited thereto.

The driving IC may be a kind of a component that processes data and driving signals for displaying an image. The driving IC may be disposed in a manner such as a Chip On Glass (COG), a Chip On Film (COF), a Chip On Panel (COP), or a Tape Carrier Package (TCP) depending on the mounting method. However, the embodiments of the present disclosure are not limited thereto. The flexible circuit board (or flexible film) 157 may be attached or bonded onto the plurality of pad electrodes PE of the pad part PAD via a conductive adhesive layer. However, the embodiments of the present disclosure are not limited thereto.

The printed circuit board 160 may be a kind of a component electrically connected to one or more flexible circuit boards (or flexible films) 157 to supply signals to the driving IC. For example, the printed circuit board 160 may supply signals to the driving IC such as a gate driver IC or a data driver IC disposed on the flexible circuit board (or flexible film) 157. The printed circuit board 160 may be disposed at one side of the flexible circuit board (or flexible film) 157 to be electrically connected to the flexible circuit board (or flexible film) 157. Various components for supplying various signals to the driving IC may be disposed on the printed circuit board 160. For example, a variety of components, including a timing controller, a power supply, a memory, a processor, or the like, may be disposed on the printed circuit board 160. For example, the printed circuit board 160 may be provided with a power management integrated circuit PMIC. However, the embodiments of the present disclosure are not limited thereto.

The printed circuit board 160 may include at least one hole 180 (see FIG. 1). However, the embodiments of the present disclosure are not limited thereto. In an area corresponding to at least one hole 180, there may be disposed an internal component detecting ambient light, temperature or the like. The internal component may include a plurality of sensors. For example, the internal component may include an ambient light sensor (ALS) or a temperature sensor. However, embodiments of the present disclosure are not limited thereto. For example, the hole 180 may be a through hole. However, the embodiments of the present disclosure are not limited thereto.

Referring to FIG. 1, the polarizing layer 293 may be disposed on the display panel 100. The polarizing layer 293 can prevent or alleviate a phenomenon in which the light generated by an external light source enters the display panel 100 and affects the light-emitting element or the like. The polarizing layer 293 can prevent or alleviate external light reflection by components of the display panel 100.

The cover member 155 may be disposed on the polarizing layer 293. The cover member 155 may be a member for protecting the display panel 100. The adhesive layer 295 may be disposed between the polarizing layer 293 and the cover member 155. For example, the cover member 155 may be disposed on the polarizing layer 293 with the adhesive layer 295 disposed therebetween. By the adhesive layer 295 the cover member 155 can be attached to the polarizing layer 293. The adhesive layer 295 may include an optically clear adhesive (OCA), an optically clear resin (OCR), a pressure sensitive adhesive (PSA), or the like. However, the embodiments of the present disclosure are not limited thereto.

The support substrate 145 may be disposed between the display panel 100 and the printed circuit board 160. The support substrate 145 can reinforce the rigidity of the display panel 100. The support substrate 145 may be a back plate. However, the embodiments of the present disclosure are not limited thereto.

Referring to FIGS. 1 to 3, the plurality of link lines LL may be disposed in the non-display area NA. The plurality of link lines LL may be wirings that transmit various signals from one or more flexible circuit boards (or flexible films) 157 and the printed circuit boards 160 to the display area AA. The plurality of link lines LL may extend from the plurality of pad electrodes PE in the second non-display area NA2 toward the bending area BA and the first non-display area NA1 to be electrically connected to a plurality of driving lines VL in the display area AA. The plurality of pixel driving circuits PD can be driven by receiving signals from one or more flexible circuit boards (or flexible films) 157 and printed circuit boards 160 through the driving lines VL in the display area AA and the link lines LL in the non-display area NA.

For example, the plurality of driving lines VL may be wirings for transmitting signals output from the flexible circuit board (or flexible film) 157 and the printed circuit board 160 to the plurality of pixel driving circuits PD together with the plurality of link lines LL. The plurality of driving lines VL may be disposed in the display area AA to be electrically connected to each of the plurality of pixel driving circuits PD. The plurality of driving lines VL may extend from the display area AA toward the non-display area NA to be electrically connected to the plurality of link lines LL. Therefore, the signals output from the flexible circuit board (or flexible film) 157 and the printed circuit board 160 may be transmitted to each of the plurality of pixel driving circuits PD through the plurality of link lines LL and the plurality of driving lines VL.

When the bending area BA is bent, portions of the plurality of link lines LL may be also bent together. Stress may be concentrated on a portion of the bent link line LL, which may cause cracks to occur in the link line LL. So, the plurality of link lines LL may be made of a conductive material having excellent ductility to reduce the cracks when the bending area BA is bent. For example, the plurality of link lines LL may be configured with a conductive material having excellent ductility, such as gold (Au), silver (Ag), aluminum (Al) or the like. However, the embodiments of the present disclosure are not limited thereto. Alternatively, the plurality of link lines LL may be configured with one of various conductive materials used in the display area AA. For example, the plurality of link lines LL may be configured with molybdenum (Mo), chromium (Cr), titanium (Ti), nickel (Ni), neodymium (Nd), copper (Cu), and an alloy of silver (Ag) and magnesium (Mg), or any alloy thereof. However, the embodiments of the present disclosure are not limited thereto. The plurality of link lines LL may be configured in a multilayer structure including various conductive materials. For example, the plurality of link lines LL may be composed of a triple layer structure. For example, the plurality of link lines LL may be configured in a triple layer structure of titanium (Ti)/aluminum (Al)/titanium (Ti). However, the embodiments of the present disclosure are not limited thereto.

The plurality of link lines LL may be configured in various shapes to reduce the stress. At least a portion of the plurality of link lines LL disposed on the bending area BA may extend in the same direction as the extension direction of the bending area BA, or in a direction different from the extension direction of the bending area BA, to reduce the stress. For example, in a case where the bending area BA extends in one direction from the first non-display area NA1 toward the second non-display area NA2, at least a portion of the link line LL disposed on the bending area BA may extend in a direction inclined with respect to the one direction. In another example, at least a portion of the plurality of link lines LL may be configured in patterns of various shapes. For example, at least a portion of the plurality of link lines LL disposed on a bending area BA may have a shape in which a conductive pattern having at least one shape of a diamond shape, a rhombus shape, a trapezoidal wave shape, a triangular wave shape, a sawtooth wave shape, a sine wave shape, a circular shape, and an omega ((2) shape may be repeatedly disposed. However, the embodiments of the present disclosure are not limited thereto. Therefore, in order to minimize or reduce the stress concentrated on the plurality of link lines LL and the resulting cracks, the shape of the plurality of link lines LL may be formed in various shapes including the shapes described above. However, the embodiments of the present disclosure are not limited thereto.

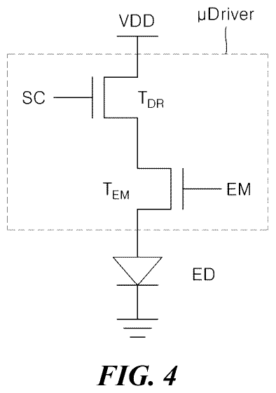

FIG. 4 is a diagram showing a circuit structure according to an exemplary embodiment of the present disclosure.

In FIG. 4, one light-emitting element ED is, by way of example, connected to a micro driver (μDriver). However, the embodiments of the present disclosure are not limited thereto. Alternatively, a plurality of light-emitting elements (EDs) may be connected to one micro driver. For example, eight light-emitting elements (LEDs) may be connected to one micro driver. In another example, sixteen light-emitting elements ED may be connected to one micro driver, or thirty two light-emitting elements ED or sixty four light-emitting elements ED may be connected to one micro driver simultaneously. The light-emitting element ED may be a micro light-emitting element (micro LED). For example, the micro driver may be configured to drive the plurality of light emitting devices ED.

One micro driver may include at least one driving transistor T_{DR} and at least one light-emission transistor T_{EM}. However, embodiments of the present disclosure are not limited thereto. For example, the micro driver may further include at least one capacitor. For example, the driving transistor T_{DR} may be configured to drive the plurality of light emitting devices ED.

For example, the driving transistor T_{DR} may have a first electrode to which a high-potential power supply voltage VDD is applied, a second electrode to which a first electrode of the light-emission transistor T_{EM} is connected, and a gate electrode to which a scan signal SC is applied. The scan signal SC applied to the gate electrode of the driving transistor T_{DR} may be a direct current (DC) power source, and a fixed reference voltage Vref may be applied every frame. However, the embodiments of the present disclosure are not limited thereto. The driving transistor TDR is turned on or off in response to the scan signal SC applied to the gate electrode of the driving transistor TDR.

The light-emission transistor T_{EM} may have the first electrode to which the second electrode of the driving transistor T_{DR} is connected, a second electrode to which the light-emitting element ED is connected, and a gate electrode to which a light-emission signal EM is applied. The light-emission signal EM applied to the gate electrode of the light-emission transistor T_{EM} may be a pulse width modulation (PWM) signal that varies every frame. However, the embodiments of the present disclosure are not limited thereto. The light-emission transistor T_{EM} is turned on or off in response to the light-emission signal EM applied to the gate electrode of the light-emission transistor T_{EM}.

The light-emitting element ED may have the first electrode connected to the second electrode of the light-emission transistor T_{EM}, and a second electrode connected to ground. For example, the first electrode may be an anode electrode, and the second electrode may be a cathode electrode. However, the embodiments of the present disclosure are not limited thereto.

Each of the transistors included in the micro driver (μDriver) may be an n-type transistor or a p-type transistor. For example, each of the driving transistor T_{DR} and the light-emission transistor T_{EM} may be an n-type or a p-type transistor.

In the micro driver, the driving transistor T_{DR} may be turned on by the scan signal SC applied from the timing controller T-CON, and the light-emitting transistor T_{EM} may be turned on by the light-emitting signal EM. When the driving transistor T_{DR} and the light-emission transistor T_{EM} are turned on, a driving current can be applied to the light-emitting element ED via the driving transistor T_{DR} and the light-emitting transistor T_{EM} by the high-potential power supply voltage VDD applied to the first electrode of the driving transistor T_{DR}, thereby causing the light-emitting element ED to emit light.

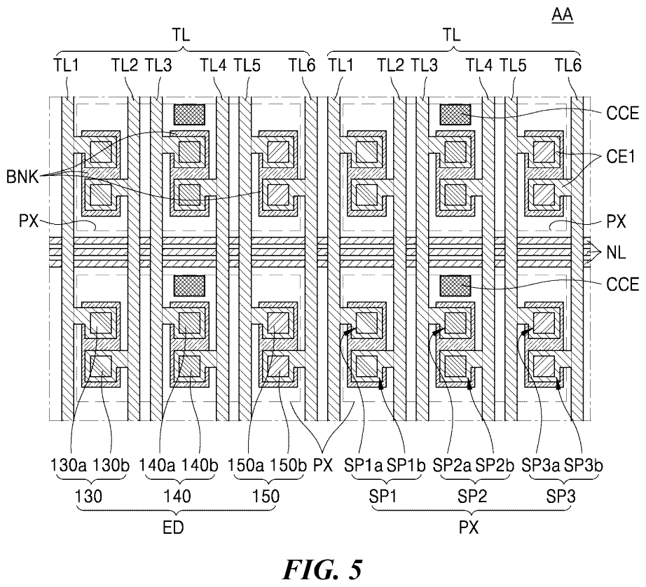

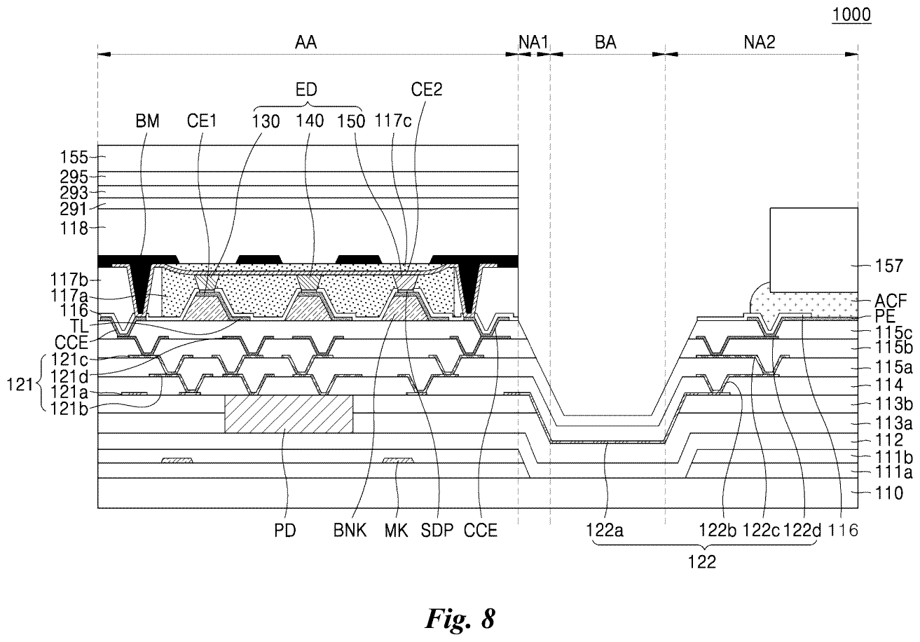

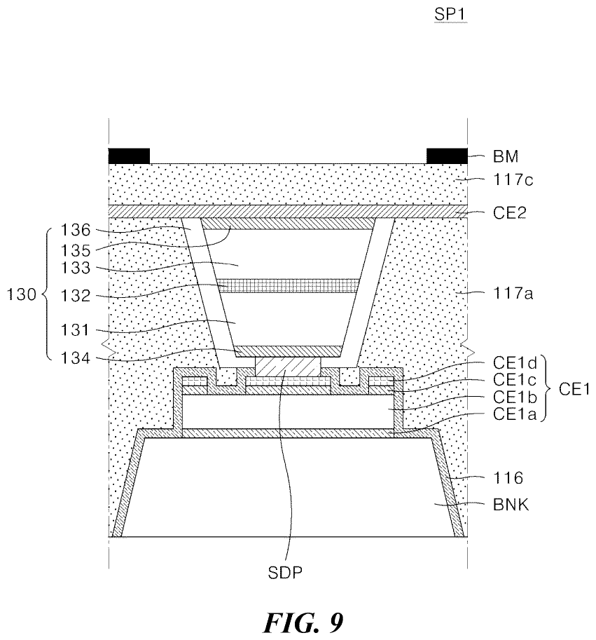

FIGS. 5 to 7 are plan views of a display device according to an exemplary embodiment of the present disclosure. FIGS. 8 and 9 are cross-sectional views of a display device according to an exemplary embodiment of the present disclosure.

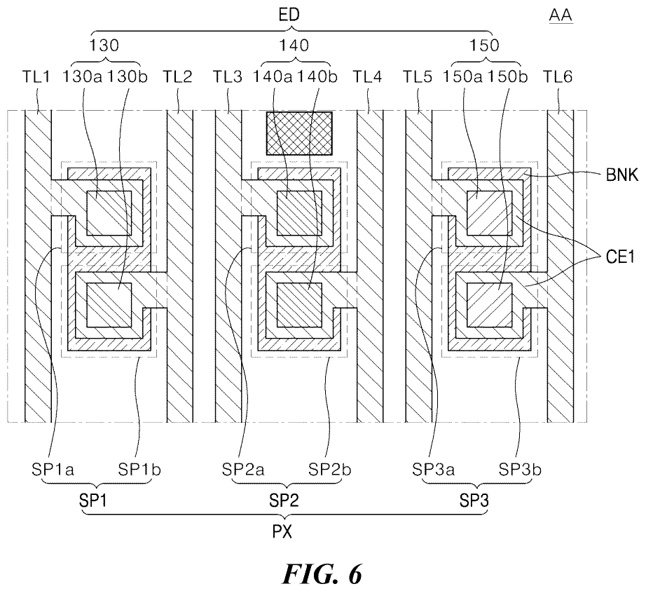

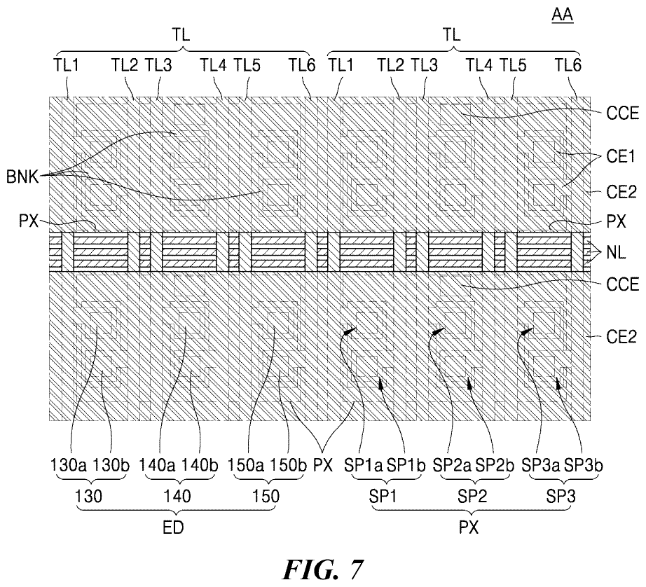

For example, FIG. 5 is an enlarged plan view of a display area including a plurality of pixels. For example, FIG. 6 is an enlarged plan view of a display area including one pixel. For example, FIG. 7 is an enlarged plan view of a display area including a plurality of pixels. For example, FIG. 8 is a cross-sectional view of the display area AA, the first non-display area NA, the bending area BA, and the second non-display area NA2. For example, FIG. 9 is a cross-sectional view of a display area including one sub-pixel SP1.

In FIGS. 5 and 6, only a plurality of signal lines TL, a plurality of communication lines NLs, a plurality of first electrodes CE1, a plurality of banks BNK, and a plurality of light-emitting elements ED are illustrated. However, the embodiments of the present disclosure are not limited thereto. FIG. 7 is an enlarged plan view in which a plurality of second electrodes CE2 are additionally disposed to FIG. 5.

Referring to FIGS. 5, 6, and 9, a plurality of pixels PX configured with a plurality of sub-pixels may be disposed in the display area AA. Each of the plurality of sub-pixels may include a light-emitting element ED, and can independently emit light. The plurality of sub-pixels may be arranged in a plurality of rows and a plurality of columns and thus may be arranged in a matrix form. However, the embodiments of the present disclosure are not limited thereto.

The plurality of sub-pixels may include a first sub-pixel SP1, a second sub-pixel SP2, and a third sub-pixel SP3. For example, one of the first sub-pixel SP1, the second sub-pixel SP2 and the third sub-pixel SP3 may be a red sub-pixel, another thereof may be a green sub-pixel, and the rest one thereof may be a blue sub-pixel. The types of the plurality of sub-pixels are given only as an example, and the embodiments of the present disclosure are not limited thereto. For example, the first sub-pixel SP1, the second sub-pixel SP2 and the third sub-pixel SP3 may be white sub-pixel, cyan sub-pixel, magenta sub-pixel, or yellow sub-pixel, etc.

Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3. The pair of first sub-pixels SP1 may include a (1-1)-th sub-pixel SP1a and a (1-2)-th sub-pixel SP1b. The pair of second sub-pixels SP2 may include a (2-1)-th sub-pixel SP2a and a (2-2)-th sub-pixel SP2b. The pair of third sub-pixels SP3 may include a (3-1)-th sub-pixel SP3a and a (3-2)-th sub-pixel SP3b. For example, one pixel PX may include a (1-1)-th sub-pixel SP1a and a (1-2)-th sub-pixel SP1b, a (2-1)-th sub-pixel SP2a and a (2-2)-th sub-pixel SP2b, and a (3-1)-th sub-pixel SP3a and a (3-2)-th sub-pixel SP3b. However, embodiments of the present disclosure are not limited thereto. More or less sub-pixels can be included in the one pixel PX.

The plurality of sub-pixels constituting one pixel PX may be arranged in various ways. For example, in one pixel PX, the pair of first sub-pixels SP1 may be disposed in the same column, the pair of second sub-pixels SP2 may be disposed in the same column, and the pair of third sub-pixels SP3 may be disposed in the same column. The first sub-pixel SP1, the second sub-pixel SP2, and the third sub-pixel SP3 may be disposed in the same row. The number and arrangement of the plurality of sub-pixels constituting one pixel PX are given only as an example, and the embodiments of the present disclosure are not limited thereto.

For example, in one pixel PX, a (1-1)-th sub-pixel SP1a and a (1-2)-th sub-pixel SP1b may be disposed in the same column, a (2-1)-th sub-pixel SP2a and a (2-2)-th sub-pixel SP2b may be disposed in the same column, and a (3-1)-th sub-pixel SP3a and a (3-2)-th sub-pixel SP3b may be disposed in the same column, and the embodiments of the present disclosure are not limited thereto.

The plurality of signal lines TL may be disposed in the area between a plurality of sub-pixels. The plurality of signal lines TL may extend in the column direction while being disposed between adjacent ones of the plurality of sub-pixels. The plurality of signal lines TL may be wirings that transmit the anode voltage from the pixel driving circuit PD to the plurality of sub-pixels. For example, the plurality of signal lines TL may be electrically connected to the plurality of pixel driving circuits PD and first electrodes CE1s of the plurality of sub-pixels. The anode voltage output from the pixel driving circuit PD may be transmitted to the first electrodes CE1s of the plurality of sub-pixels through the plurality of signal lines TL. For example, the first electrode CE1 may be an electrode electrically connected to an anode electrode 134 of the light-emitting element ED. By this, the anode voltage from the signal line TL can be transmitted to the anode electrode 134 of the light-emitting element ED through the first electrode CE1.

Therefore, instead of forming a plurality of transistors and storage capacitors in each of the plurality of sub-pixels, by using the pixel driving circuit PD in which a plurality of pixel circuits are integrated, the structure of the display device 1000 can be simplified. In addition, since the circuits disposed in each of the plurality of sub-pixels are integrated into one pixel driving circuit PD, high-efficiency and low-power driving can be realized.

The plurality of signal lines TL may include a first signal line TL1, a second signal line TL2, a third signal line TL3, a fourth signal line TL4, a fifth signal line TL5, and a sixth signal line TL6. Each of the first signal line TL1 and the second signal line TL2 may be electrically connected to the pair of first sub-pixels SP1. Each of the third signal line TL3 and the fourth signal line TL4 may be electrically connected to the pair of second sub-pixels SP2. Each of the fifth signal line TL5 and the sixth signal line TL6 may be electrically connected to the pair of third sub-pixels SP3.

The first signal line TL1 and the second signal line TL2 may be electrically connected to the pair of first sub-pixels SP1. The first signal line TL1 may be disposed at one side of the pair of first sub-pixels SP1, and the second signal line TL2 may be disposed at the other side of the pair of first sub-pixels SP1. The first signal line TL1 may be electrically connected to the first electrode CE1 of one of the first sub-pixels SP1 of the pair of first sub-pixels SP1, for example, the (1-1)-th sub-pixel SP1a. The second signal line TL2 may be electrically connected to the first electrode CE1 of the remaining first sub-pixel SP1 of the pair of first sub-pixels SP1, for example, the (1-2)-th sub-pixel SP1b.

The third signal line TL3 and the fourth signal line TL4 may be electrically connected to the pair of second sub-pixels SP2. The third signal line TL3 may be disposed at one side of the pair of second sub-pixels SP2, and the fourth signal line TL4 may be disposed at the other side of the pair of second sub-pixels SP2. For example, the third signal line TL3 may be disposed neighboring the second signal line TL2. The third signal line TL3 may be electrically connected to the first electrode CE1 of one of the second sub-pixels SP2 of the pair of second sub-pixels SP2, for example, the (2-1)-th sub-pixel SP2a. The fourth signal line TL4 may be electrically connected to the first electrode CE1 of the remaining second sub-pixel SP2 of the pair of second sub-pixels SP2, for example, the (2-2)-th sub-pixel SP2b.

The fifth signal line TL5 and the sixth signal line TL6 may be electrically connected to the pair of third sub-pixels SP3. The fifth signal line TL5 may be disposed at one side of the pair of third sub-pixels SP3, and the sixth signal line TL6 may be disposed at the other side of the pair of third sub-pixels SP3. For example, the fifth signal line TL5 may be disposed neighboring the fourth signal line TL4. The sixth signal line TL6 may be disposed neighboring the first signal line TL1 connected to the neighboring pixel PX. The fifth signal line TL5 may be electrically connected to the first electrode CE1 of one of the third sub-pixels SP3 of the pair of third sub-pixels SP3, for example, the (3-1)-th sub-pixel SP3a. The sixth signal line TL6 may be electrically connected to the first electrode CE1 of the remaining third sub-pixel SP3 of the pair of third sub-pixels SP3, for example, the (3-2)-th sub-pixel SP3b.

For example, the first signal line TL1 and the second signal line TL2 may be electrically connected to the (1-1)-th sub-pixel SP1a and the (1-2)-th sub-pixel SP1b, respectively, the third signal line TL3 and the fourth signal line TL4 may be electrically connected to the (2-1)-th sub-pixel SP2a and the (2-2)-th sub-pixel SP2b, respectively, and the fifth signal line TL5 and the sixth signal line TL6 may be electrically connected to the (3-1)-th sub-pixel SP3a and a (3-2)-th sub-pixel SP3b, respectively, and the embodiments of the present disclosure are not limited thereto.

The plurality of signal lines TL may be made of a conductive material. For example, the plurality of signal lines TL may be made of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like. However, the embodiments of the present disclosure are not limited thereto. In another example, the plurality of signal lines TL may be formed of a multilayer structure of conductive material. For example, the plurality of signal lines TL may be configured in a multilayer structure of titanium (Ti)/aluminum (Al)/titanium (Ti)/indium tin oxide (ITO). However, the embodiments of the present disclosure are not limited thereto.

The plurality of communication lines NLs may be disposed in an area between the plurality of pixels PX. The plurality of communication lines NLs may be disposed to extend in the row direction in the area between adjacent ones of the plurality of pixels PX. The plurality of communication lines NLs may be disposed in an area between adjacent ones of the plurality of second electrodes CE2s, and may not overlap with the plurality of second electrodes CE2s. For example, the plurality of communication lines NL may be wirings used for short-range communication such as Near Field Communication (NFC). The plurality of communication lines NL may function as antennas. For example, the plurality of communication lines NL may be a plurality of connection lines or the like. However, the embodiments of the present disclosure are not limited thereto.

According to the present disclosure, the bank BNK may be disposed in each of the plurality of sub-pixels. A plurality of banks BNK may be structures on which a plurality of light-emitting elements ED are mounted. The plurality of banks BNK can guide the positions of the plurality of light-emitting elements ED in a transfer process of transferring the plurality of light-emitting elements ED to the display device 1000. In a transfer process of a plurality of light-emitting elements ED, a plurality of light-emitting elements ED may be transferred onto a plurality of banks BNK. The plurality of banks BNK may be bank patterns or bank structures. However, the embodiments of the present disclosure are not limited thereto.

The bank BNK of the first sub-pixel SP1, the bank BNK of the second sub-pixel SP2, and the bank BNK of the third sub-pixel SP3 may be disposed spaced apart from each other. The bank BNK of the first sub-pixel SP1, the bank BNK of the second sub-pixel SP2, and the bank BNK of the third sub-pixel SP3 may be configured to be separated from each other. Accordingly, the banks BNK of the first sub-pixel SP1, the second sub-pixel SP2, and the third sub-pixel SP3 to which different types of light-emitting elements ED are transferred can be easily identified.

The bank BNK of the (1-1)-th sub-pixel SP1a and the bank BNK of the (1-2)-th sub-pixel SP1b may be connected to each other, or may be formed to be spaced apart or separated from each other. For example, depending on the consideration of design requirements and the like of the transfer process, the bank BNK of the (1-1)-th sub-pixel SP1a and the bank BNK of the (1-2)-th sub-pixel SP1b in which the light-emitting elements ED of the same type are disposed may be connected to each other, or may be spaced apart or separated from each other. And, the bank BNK of the (2-1)-th sub-pixel SP2a and the bank BNK of the (2-2)-th sub-pixel SP2b may be connected to each other, or may be formed to be spaced apart or separated from each other. The bank BNK of the (3-1)-th sub-pixel SP3a and the bank BNK of the (3-2)-th sub-pixel SP3b may be connected to each other, or may be formed to be spaced apart or separated from each other. Accordingly, the banks BNK of the pair of first sub-pixels SP1, the banks BNK of the pair of second sub-pixels SP2, and the banks BNK of the pair of third sub-pixels SP3 can be formed in various ways, and so the embodiments of the present disclosure are not limited thereto.

For example, the plurality of banks BNK may be made of an organic insulating material. The plurality of banks BNK may be configured in a single-layer or multi-layer structure of organic insulating material. For example, the plurality of banks BNK may be made of a photoresist, polyimide (PI), or acrylic-based material, or the like. However, the embodiments of the present disclosure are not limited thereto. The plurality of banks BNK may be made of, for example, a transparent carbon-based mixture. Specifically, the plurality of banks BNK may contain carbon black, but is not limited thereto. The plurality of banks BNK may also be made of a transparent insulating material. However, the embodiments of the present disclosure are not limited thereto.

The first electrode CE1 may be disposed on each of the plurality of sub-pixels. The first electrode CE1 may be disposed on the bank BNK. The first electrode CE1 may be electrically connected to one of the plurality of signal lines TL. At least a portion of the first electrode CE1 may extend outside of the bank BNK to be electrically connected to a signal line TL closest to the first electrode CE1. For example, a portion of the first electrode CE1 of the (1-1)-th sub-pixel SP1a may extend to one side area of the (1-1)-th sub-pixel SP1a to be electrically connected to the first signal line TL1, and a portion of the first electrode CE1 of the (1-2)-th sub-pixel SP1b may extend to the other side area of the (1-2)-th sub-pixel SP1b to be electrically connected to the second signal line TL2. A portion of the first electrode CE1 of the (2-1)-th sub-pixel SP2a may extend to one side area of the (2-1)-th sub-pixel SP2a to be electrically connected to the third signal line TL3, and a portion of the first electrode CE1 of the (2-2)-th sub-pixel SP2b may extend to the other side area of the (2-2)-th sub-pixel SP2b to be electrically connected to the fourth signal line TL4. A portion of the first electrode CE1 of the (3-1)-th sub-pixel SP3a may extend to one side area of the (3-1)-th sub-pixel SP3a to be electrically connected to the fifth signal line TL5, and a portion of the first electrode CE1 of the (3-2)-th sub-pixel SP3b may extend to the other side area of the (3-2)-th sub-pixel SP3b to be electrically connected to the sixth signal line TL6.

The first electrode CE1 may be electrically connected to the anode electrode 134 of the light-emitting element ED to transmit the anode voltage from the pixel driving circuit PD to the light-emitting element ED through the signal line TL. To the first electrode CE1 of each of the plurality of sub-pixels, a different voltage may be applied depending on the image to be displayed. For example, a different voltage may be applied to the first electrode CE1 of each of the plurality of sub-pixels. The first electrode CE1 may be a pixel electrode, and the embodiments of the present disclosure are not limited thereto.

The first electrode CE1 may be made of a conductive material. For example, the first electrode CE1 may be configured as one body with a plurality of signal lines TL. For example, the first electrode CE1 may be made of the same conductive material as the plurality of signal lines TL. However, the embodiments of the present disclosure are not limited thereto. For example, the first electrode CE1 may be made of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like. However, the embodiments of the present disclosure are not limited thereto. In another example, the first electrode CE1 may be configured in a multilayer structure of conductive material. For example, the plurality of first electrode CE1 may be configured in a multilayer structure of titanium (Ti)/aluminum (Al)/titanium (Ti)/indium tin oxide (ITO). However, the embodiments of the present disclosure are not limited thereto.

For example, the first electrode CE1 may have a multilayer structure including a transparent conductive film and an opaque conductive film having high reflective efficiency. The transparent conductive film may be made of a material having a relatively high work function value such as indium-tin-oxide (ITO) or indium-zinc-oxide (IZO), and the opaque conductive film may have a single-layer or multi-layer structure including Al, Ag, Cu, Pb, Mo, Ti or an alloy thereof. However, the embodiments of the present disclosure are not limited thereto.

The light-emitting element ED may be disposed in each of the plurality of sub-pixels. The plurality of light-emitting elements ED may be any one of a light-emitting diode (LED) and a micro light-emitting diode (Micro LED). However, the embodiments of the present disclosure are not limited thereto. The plurality of light-emitting elements ED may be disposed on the bank BNK and the first electrode CE1. Each of the plurality of light-emitting elements ED may be disposed on the first electrode CE1 to be electrically connected to the first electrode CE1. Therefore, the light-emitting element ED can emit light by receiving an anode voltage from the pixel driving circuit PD through the signal line TL and the first electrode CE1.

Each of the plurality of light-emitting elements ED may include a first light-emitting element 130, a second light-emitting element 140, and a third light-emitting element 150. The first light-emitting element 130 may be disposed in the first sub-pixel SP1. The second light-emitting element 140 may be disposed in the second sub-pixel SP2. The third light-emitting element 150 may be disposed in the third sub-pixel SP3. For example, one of the first light-emitting element 130, the second light-emitting element 140, and the third light-emitting element 150 may be a red light-emitting element, another thereof may be a green light-emitting element, and the rest one thereof may be blue light-emitting elements. However, the embodiments of the present disclosure are not limited thereto. Accordingly, by combining red light, green light, and blue light emitted from the plurality of light-emitting elements ED, light of various colors, including white, can be implemented. The types of the plurality of light-emitting elements ED are given only as an example, and the embodiments of the present disclosure are not limited thereto.

The first light-emitting element 130 may include a plurality of the light-emitting elements disposed in the pair of first sub-pixels SP1, the second light-emitting element 140 may include plurality of the light-emitting elements disposed in the pair of second sub-pixels SP2, and the third light-emitting element 150 may include a plurality of the light-emitting elements disposed in the pair of third sub-pixels SP3. However, embodiments of the present disclosure are not limited thereto.

The first light-emitting element 130 may include a (1-1)-th light-emitting element 130a disposed in the (1-1)-th sub-pixel SP1a and a (1-2)-th light-emitting element 130b disposed in the (1-2)-th sub-pixel SP1b. The second light-emitting element 140 may include a (2-1)-th light-emitting element 140a disposed in the (2-1)-th sub-pixel SP2a and a (2-2)-th light-emitting element 140b disposed in the (2-2)-th sub-pixel SP2b. The third light-emitting element 150 may include a (3-1)-th light-emitting element 150a disposed in the (3-1)-th sub-pixel SP3a and a (3-2)-th light-emitting element 150b disposed in the (3-2)-th sub-pixel SP3b.

Referring to FIGS. 5, 6, 7, and 9 together, the second electrode CE2 may be disposed on each of the plurality of sub-pixels. The second electrode CE2 may be disposed on the light-emitting element ED. The second electrode CE2 may be electrically connected to the pixel driving circuit PD through a plurality of contact electrodes CCE.

For example, the second electrode CE2 may be electrically connected to the cathode electrode 135 of the light-emitting element ED to transmit the cathode voltage from the pixel driving circuit PD to the light-emitting element ED. The same cathode voltage may be applied to the second electrode CE2 of each of the plurality of sub-pixels. For example, the same voltage may be applied to the second electrode CE2 of each of the plurality of sub-pixels and the cathode electrode 135 of the light-emitting element ED. The second electrode CE2 may be a common electrode. However, the embodiments of the present disclosure are not limited thereto.

At least some of the plurality of sub-pixels may share the second electrode CE2 with each other. At least some of the second electrodes CE2 of the plurality of respective sub-pixels may be electrically connected to each other. As the same voltage is applied to the second electrodes CE2, the second electrode CE2 can be shared to be used for at least some sub-pixels. For example, the second electrodes CE2 of at least some of the pixels PX among the plurality of pixels PX disposed in the same row may be connected to each other. For example, one second electrode CE2 may be disposed on a plurality of pixels PX. For example, one second electrode CE2 may be disposed for every n sub-pixels.

For example, some of the second electrodes CE2 of the plurality of respective sub-pixels may be disposed to be spaced apart from or separated from each other. For example, the second electrode CE2 connected to the pixels PX of the n-th row and the second electrode CE2 connected to the pixels PX of the (n+1)-th row may be disposed to be spaced apart from each other or separated from each other. For example, the plurality of second electrodes CE2 may be disposed to be spaced apart from each other with a plurality of communication lines NL interposed and extending therebetween in the row direction. Thus, the number of the plurality of sub-pixels can be greater than the number of the plurality of second electrodes CE2. In another example, all of the second electrodes CE2 of a plurality of sub-pixels may be connected to each other so that only one second electrode CE2 is placed on the substrate 110. However, the embodiments of the present disclosure are not limited thereto.

The plurality of second electrodes CE2 may be made of a transparent conductive material. However, the embodiments of the present disclosure are not limited thereto. The plurality of second electrodes CE2 may be made of a transparent conductive material, so that light emitted from the light-emitting element ED can be directed upward beyond the second electrodes CE2. For example, the second electrode CE2 may be made of a transparent conductive material such as indium tin oxide (ITO), indium zinc oxide (IZO), indium gallium zinc oxide (IGZO), or the like. However, the embodiments of the present disclosure are not limited thereto. The second electrode CE2 may be a transparent electrode.

For example, the second electrode CE2 may have a multilayer structure including a transparent conductive film and an opaque conductive film having high reflective efficiency. The transparent conductive film may be made of a material having a relatively high work function value such as indium-tin-oxide (ITO) or indium-zinc-oxide (IZO), and the opaque conductive film may have a single-layer or multi-layer structure including Al, Ag, Cu, Pb, Mo, Ti or an alloy thereof. However, the embodiments of the present disclosure are not limited thereto.

The plurality of contact electrodes CCE may be disposed on the substrate 110. For example, the plurality of contact electrodes CCE may be disposed to be spaced apart from the plurality of banks BNK and the plurality of signal lines TL. Each of the plurality of second electrodes CE2 may overlap with at least one contact electrode CCE. For example, one second electrode CE2 may overlap with the plurality of contact electrodes CCE.

For example, a plurality of contact electrodes CCE may be electrically connected to a plurality of second electrodes CE2. The plurality of contact electrodes CCE may be disposed between the substrate 110 and the plurality of second electrodes CE2 to transmit the cathode voltage from the pixel driving circuit PD to the second electrodes CE2.

For example, in a case where a micro LED is used as the light-emitting element ED, a plurality of micro LEDs may be formed on a wafer, and the micro LEDs may be transferred to the substrate 110 of the display device 1000 to manufacture the display device 1000. In the process of transferring a plurality of light-emitting elements ED having a microscopic size from the wafer to the substrate 110, various defects may be formed. For example, in some sub-pixels, a non-transfer defect may occur in which the light-emitting element ED is not transferred, and in other some sub-pixels, a defect may occur in which the light-emitting element ED is transferred outside the predetermined position due to an alignment error. Additionally, although the transfer process has been performed normally, the transferred light-emitting element ED itself may be defective. Therefore, taking into account the defects produced during the transfer process of the plurality of light-emitting elements ED, a plurality of light-emitting elements ED of the same type may be transferred to one sub-pixel. Lighting tests may be performed on the plurality of light-emitting elements ED, and only one light-emitting element ED that is ultimately judged to be normal may be used.

For example, the (1-1)-th light-emitting element 130a and the (1-2)-th light-emitting element 130b may be transferred together to one pixel PX, and may be tested to find whether they are defective or not. If both the (1-1)-th light-emitting element 130a and the (1-2)-th light-emitting element 130b are determined to be normal, only the (1-1)-th light-emitting element 130a may be used, and the (1-2)-th light-emitting element 130b may not be used, without being limited thereto. For example, if both the (1-1)-th light-emitting element 130a and the (1-2)-th light-emitting element 130b are determined to be normal, only the (1-1)-th light-emitting element 130a may not be used, and the (1-2)-th light-emitting element 130b may be used. In another example, if only the (1-2)-th light-emitting element 130b among the (1-1)-th light-emitting element 130a and the (1-2)-th light-emitting element 130b is judged to be normal, the (1-1)-th light-emitting element 130a may not be used and only the (1-2)-th light-emitting element 130b may be used. Therefore, even if a plurality of light-emitting elements ED of the same type are transferred to one pixel PX, only one light-emitting element ED can be used ultimately.

Accordingly, one of the pair of light-emitting elements ED may be a main or primary light-emitting element ED, and the other light-emitting element ED thereof may be a redundant light-emitting element ED or a spare light-emitting element ED. The redundant light-emitting element ED may be a spare light-emitting element ED that has been transferred to cope with failure of the main light-emitting element ED. In case of the failure of the main light-emitting element ED, the redundant light-emitting element ED can be used as a replacement for it. Therefore, by transferring the main light-emitting element ED and the redundant light-emitting element ED together to one pixel PX, the deterioration of display quality due to defects in light-emitting element ED itself can be minimized or reduced.

For example, the (1-1)-th light-emitting element 130a, the (2-1)-th light-emitting element 140a, and the (3-1)-th light-emitting element 150a transferred to one pixel PX may be used as main light-emitting elements ED, while the (1-2)-th light-emitting element 130b, the (2-2)-th light-emitting element 140b, and the (3-2)-th light-emitting element 150b may be used as redundant light-emitting elements ED. In case of the failure of the (1-1)-th light-emitting element 130a, the (2-1)-th light-emitting element 140a, and the (3-1)-th light-emitting element 150a, the (1-2)-th light-emitting element 130b, the (2-2)-th light-emitting element 140b, and the (3-2)-th light-emitting element 150b can be used as a replacement for it.

FIG. 8 is a cross-sectional view of a display device according to an exemplary embodiment of the present disclosure. FIG. 9 is a cross-sectional view of a display device according to an exemplary embodiment of the present disclosure. For example, FIG. 8 is a cross-sectional view of the display area AA, the first non-display area NA1, the bending area BA, and the second non-display area NA2. For example, FIG. 9 is a cross-sectional view of a display area including one sub-pixel SP1.

Referring to FIG. 8, in the remaining area of the substrate 110 except the bending area BA a first buffer layer 111a and a second buffer layer 111b may be disposed.

The first buffer layer 111a and the second buffer layer 111b may be disposed in the display area AA, the first non-display area NA1, and the second non-display area NA2 and may not be arranged in the entirety or part of the bending area BA. The first buffer layer 111a and the second buffer layer 111b may reduce the penetration of moisture or impurities through the substrate 110. The first buffer layer 111a and the second buffer layer 111b may be made of an inorganic insulating material. For example, the first buffer layer 111a and the second buffer layer 111b may be configured in a single-layer or multi-layer structure of silicon oxide (SiOx) or silicon nitride (SiNx). However, the embodiments of the present disclosure are not limited thereto.

For example, a portion of the first buffer layer 111a and the second buffer layer 111b on the bending area BA may be removed. The upper surface of the substrate 110 located in the bending area BA may be exposed from the first buffer layer 111a and the second buffer layer 111b. By removing the first buffer layer 111a and the second buffer layer 111b made of an inorganic insulating material from the bending area BA, it is possible to minimize or reduce the cracks that may be produced in the first buffer layer 111a and the second buffer layer 111b when being bent.

Between the first buffer layer 111a and the second buffer layer 111b a plurality of alignment keys MK may be disposed. The plurality of alignment keys MK may be configured to identify the position of the pixel driving circuit PD during the manufacturing process of the display device 1000. For example, the plurality of alignment keys MK may be configured to align the position of the pixel driving circuit PD transferred on an adhesive layer 112. In another example, the plurality of alignment keys MK may be omitted.

The adhesive layer 112 may be disposed on the second buffer layer 111b. The adhesive layer 112 may be disposed in the display area AA, the first non-display area NA1, the bending area BA, and the second non-display area NA2. In another example, at least a portion of the adhesive layer 112 may be removed from the non-display area NA including the bending area BA. For example, the adhesive layer 112 may be made of any one of an adhesive polymer, an epoxy resin, a UV-curable resin, a polyimide resin, an acrylate resin, a urethane resin, and polydimethylsiloxane (PDMS). However, the embodiments of the present disclosure are not limited thereto.

The pixel driving circuit PD may be disposed on the adhesive layer 112 in the display area AA. In a case where the pixel driving circuit PD is implemented with a driving chip, the driving chip may be mounted on the adhesive layer 112 by a transfer process. However, the embodiments of the present disclosure are not limited thereto.

A first protective layer 113a and a second protective layer 113b may be disposed on the adhesive layer 112. For example, at least one of the first protective layer 113a and the second protective layer 113b may be disposed on the adhesive layer 112, without being limited thereto. In some cases, at least one additional protection layer may be further included. The first protective layer 113a and the second protective layer 113b may be disposed to surround the side surface of the pixel driving circuit PD. However, the embodiments of the present disclosure are not limited thereto. For example, the second protective layer 113b may be disposed to cover at least a portion of the upper surface of the pixel driving circuit PD. For example, at least one of the first protective layer 113a and the second protective layer 113b disposed on the bending area BA may be omitted. For example, the first protective layer 113a may be disposed entirely in the display area AA and the non-display area NA, and the second protective layer 113b may be disposed in part in the display area AA, the first non-display area NA1, and the second non-display area NA2. For example, a portion of the second protective layer 113b may be removed in the bending area BA. However, the embodiments of the present disclosure are not limited thereto.

The first protective layer 113a and the second protective layer 113b may be made of an organic insulating material. For example, at least one of the first protective layer 113a and the second protective layer 113b may be made of an organic insulating material (e.g., organic layer). However, the embodiments of the present disclosure are not limited thereto. For example, the first protective layer 113a and the second protective layer 113b may be made of a photoresist, polyimide (PI), or photo acryl-based material, or the like. However, the embodiments of the present disclosure are not limited thereto. For example, the first protective layer 113a and the second protective layer 113b may be an overcoat layer or an insulating layer. However, the embodiments of the present disclosure are not limited thereto.

According to the present disclosure, a plurality of first connection lines 121 may be disposed on the second protective layer 113b in the display area AA. The plurality of first connection lines 121 may be wirings for electrically connecting the pixel driving circuit PD with another component. For example, a pixel driving circuit PD may be electrically connected to the plurality of signal lines TL, the plurality of contact electrodes CCE and the like through the plurality of first connection lines 121. For example, the plurality of first connection lines 121 may include a (1-1)-th connection line 121a, a (1-2)-th connection line 121b, a (1-3)-th connection line 121c, and a (1-4)-th connection line 121d. However, the embodiments of the present disclosure are not limited thereto. For example, a (1-1)-th connection line 121a, a (1-2)-th connection line 121b, a (1-3)-th connection line 121c, and a (1-4)-th connection line 121d may be arranged in different metal layers.

For example, a plurality of (1-1)-th connection lines 121a may be disposed on the second protective layer 113b. The plurality of (1-1)-th connection lines 121a may be electrically connected to the pixel driving circuit PD. The plurality of (1-1)-th connection lines 121a can transmit a voltage output from the pixel driving circuit PD to the first electrode CE1 or the second electrode CE2.

For example, a third protective layer 114 may be disposed on the second protective layer 113b, without being limited thereto. For example, at least one additional protection layer may be further included. The protective layer 114 may be disposed entirely in the display area AA and the non-display area NA. In the bending area BA, the third protective layer 114 may cover the side surface of the second protective layer 113b and the upper surface of the first protective layer 113a. The third protective layer 114 may be made of an organic insulating material. For example, the third protective layer 114 may be made of a photoresist, polyimide (PI), or photo acryl-based material, or the like. However, the embodiments of the present disclosure are not limited thereto. For example, the first protective layer 113a, the second protective layer 113b, and the third protective layer 114 may be made of the same material. However, the embodiments of the present disclosure are not limited thereto. Alternatively, the first protective layer 113a, the second protective layer 113b, and the third protective layer 114 may be composed of a different insulating material from the rest. However, the embodiments of the present disclosure are not limited thereto.

A plurality of (1-2)-th connection lines 121b may be disposed on the third protective layer 114. The plurality of (1-2)-th connection lines 121b may be electrically connected to or directly connected to the pixel driving circuit PD. For example, a portion of the (1-2)-th connection line 121b may be directly or indirectly connected to the pixel driving circuit PD through the contact hole in the third protective layer 114. Another portion of the (1-2)-th connection line 121b may be electrically connected to the (1-1)-th connection line 121a through the contact hole in the third protective layer 114. However, the embodiments of the present disclosure are not limited thereto. The voltage output from the pixel driving circuit PD may be transmitted to the first electrode CE1 or the second electrode CE2 through a connection line different from the plurality of (1-2)-th connection lines 121b.

A first insulating layer 115a may be disposed on the plurality of (1-2)-th connection lines 121b. The first insulating layer 115a may be disposed entirely in the display area AA and the non-display area NA. However, the embodiments of the present disclosure are not limited thereto. The first insulating layer 115a may be made of an organic insulating material. However, the embodiments of the present disclosure are not limited thereto. For example, the first insulating layer 115a may be made of a photoresist, polyimide (PI), or photo acryl-based material, or the like. However, the embodiments of the present disclosure are not limited thereto.

A plurality of (1-3)-th connection lines 121c may be disposed on the first insulating layer 115a. The plurality of (1-3)-th connection lines 121c may be electrically connected to the plurality of (1-2)-th connection lines 121b. For example, the (1-3)-th connection line 121c may be electrically connected to the (1-2)-th connection line 121b through the contact hole in the first insulating layer 115a.

A second insulating layer 115b may be disposed on the plurality of (1-3)-th connection lines 121c. The second insulating layer 115b may be disposed in the remaining area except the bending area BA. However, the embodiments of the present disclosure are not limited thereto. The second insulating layer 115b may be disposed in the display area AA, the first non-display area NA1, and the second non-display area NA2, and may not be disposed in the entirety or part of the bending area BA, but the embodiments of the present disclosure are not limited thereto. The second insulating layer 115b may be disposed in the display area AA, the first non-display area NA1, and the second non-display area NA2. However, the embodiments of the present disclosure are not limited thereto. For example, a portion of the second insulating layer 115b disposed in the bending area BA may be removed. The second insulating layer 115b may be made of an organic insulating material. However, the embodiments of the present disclosure are not limited thereto. For example, the second insulating layer 115b may be made of a photoresist, polyimide (PI), or photo acryl-based material, or the like. However, the embodiments of the present disclosure are not limited thereto.

A plurality of (1-4)-th connection lines 121d may be disposed on the second insulating layer 115b. The plurality of (1-4)-th connection lines 121d may be electrically connected to the plurality of (1-3)-th connection lines 121c. For example, the (1-4)-th connection line 121d may be electrically connected to the (1-3)-th connection line 121c through the contact hole in the second insulating layer 115b.

According to the present disclosure, a plurality of second connection lines 122 may be disposed on the second protective layer 113b in the non-display area NA. The plurality of second connection lines 122 may be wirings for transmitting, to the pixel driving circuit PD in the display area AA, signals transmitted from the flexible circuit board (or flexible film) 157 and the printed circuit board 160 (see FIG. 1) to the pad part PAD. For example, the plurality of second connection lines 122 may be electrically connected to the plurality of pad electrodes PE to receive signals from the flexible circuit board (or flexible film) 157 and the printed circuit board.

For example, the plurality of second connection lines 122 may extend from the pad part PAD toward the display area AA to transmit signals to the wirings of the display area AA. In this case, the plurality of second connection lines 122 may function as the link lines LL. The plurality of second connection lines 122 may include a (2-1)-th connection line 122a, a (2-2)-th connection line 122b, a (2-3)-th connection line 122c, and a (2-4)-th connection line 122d, without being limited thereto. More or less connection lines may be included.

A plurality of (2-1)-th connection lines 122a may be disposed on the second protective layer 113b. The plurality of (2-1)-th connection lines 122a may extend from the second non-display area NA2 to the bending area BA and the first non-display area NA1. The plurality of (2-1)-th connection lines 122a may transmit, to the pixel driving circuit PD of the display area AA, signals transmitted from the flexible circuit board (or flexible film) 157 and the printed circuit board to the pad part PAD.

A plurality of (2-2)-th connection lines 122b may be disposed on the third protective layer 114. The plurality of (2-2)-th connection lines 122b may be disposed in the second non-display area NA2. The (2-2)-th connection line 122b may be electrically connected to the (2-1)-th connection line 122a through the contact hole in the third protective layer 114. Accordingly, signals from the flexible circuit board (or flexible film) 157 and the printed circuit board can be transmitted to the (2-1)-th connection line 122a through the (2-2)-th connection line 122b.

The (2-3)-th connection line 122c may be disposed on the first insulating layer 115a. The (2-3)-th connection line 122c may be disposed in the second non-display area NA2. The (2-3)-th connection line 122c may be electrically connected to the (2-2)-th connection line 122b through the contact hole in the first insulating layer 115a. Accordingly, signals from the flexible circuit board (or flexible film) 157 and the printed circuit board can be transmitted to the (2-1)-th connection line 122a through the (2-3)-th connection line 122c and the (2-2)-th connection line 122b.

The (2-4)-th connection line 122d may be disposed on the second insulating layer 115b. The (2-4)-th connection line 122d may be disposed in the second non-display area NA2. The (2-4)-th connection line 122d may be electrically connected to the (2-3)-th connection line 122c through the contact hole in the second insulating layer 115b. Accordingly, signals from the flexible film (157) and the printed circuit board can be transmitted to the (2-1)-th connection line 122a through the (2-4)-th connection line 122d, the 2-3 connection line 122c and the (2-2)-th connection line 122b.

The plurality of first connection lines 121 and the plurality of second connection lines 122 may be made of any one of various conductive materials used in the display area AA or a conductive material having excellent ductility. For example, the second connection line 122 whose portion is disposed in the bending area may be made of a conductive material having excellent ductility, such as gold (Au), silver (Ag), aluminum (Al) or the like. However, the embodiments of the present disclosure are not limited thereto. In another example, the plurality of first connection line 121 and the plurality of second connection line 122 may be made of molybdenum (Mo), chromium (Cr), titanium (Ti), nickel (Ni), neodymium (Nd), copper (Cu), and an alloy of silver (Ag) and magnesium (Mg), or any alloy thereof. However, the embodiments of the present disclosure are not limited thereto.

The third insulating layer 115c may be disposed on a plurality of first connection lines 121 and a plurality of second connection lines 122. The third insulating layer 115c may be disposed in the remaining area except the bending area BA. However, the embodiments of the present disclosure are not limited thereto. The third insulating layer 115c may be disposed in the display area AA, the first non-display area NA1, and the second non-display area NA2, and may not be disposed in the entirety or part of the bending area BA, but the embodiments of the present disclosure are not limited thereto. The third insulating layer 115c may be disposed in the display area AA, the first non-display area NA1, and the second non-display area NA2. A portion of the third insulating layer 115c in the bending area BA may be removed. The third insulating layer 115c may be made of an organic insulating material. However, the embodiments of the present disclosure are not limited thereto. For example, the third insulating layer 115c may be made of a photoresist, polyimide (PI), or photo acryl-based material, or the like. However, the embodiments of the present disclosure are not limited thereto.

A plurality of banks BNK may be disposed on the third insulating layer 115c in the display area AA. The plurality of banks BNK may be disposed to overlap with each of the plurality of sub-pixels. On the upper side of each of the plurality of banks BNK one or more light-emitting elements ED of the same kind may be disposed. The bank BNK may be configured with an organic insulating material. However, the embodiments of the present disclosure are not limited thereto. For example, the bank BNK may be made of a photoresist, polyimide (PI), or photo acryl-based material, or the like. However, the embodiments of the present disclosure are not limited thereto. The bank BNK may be made of, for example, a transparent carbon-based mixture. Specifically, the bank BNK may contain carbon black, but is not limited thereto. The bank BNK may also be made of a transparent insulating material. However, the embodiments of the present disclosure are not limited thereto.

A plurality of signal lines TL may be disposed on the third insulating layer 115c in the display area AA. The plurality of signal lines TL may be disposed in the area between the plurality of banks BNK. For example, the plurality of signal lines TL may be disposed adjacent to any one of the plurality of banks BNK.

A plurality of contact electrodes CCE can be disposed on the third insulating layer 115c in the display area AA. The plurality of contact electrodes CCE may supply the cathode voltage from the pixel driving circuit PD to the second electrode CE2.

The first electrode CE1 may be disposed on the bank BNK. For example, the first electrode CE1 may be disposed to extend from the adjacent signal line TL toward the upper surface of the bank BNK. The first electrode CE1 may be disposed on the upper surface of the bank BNK and on the side surface of the bank BNK. For example, the first electrode CE1 may be disposed to extend from the signal line TL on the upper surface of the third insulating layer 115c to the side surface of the bank BNK and the upper surface of the bank BNK.

Referring to FIG. 9, the first electrode CE1 may be made of a plurality of conductive layers. For example, the first electrode CE1 may include a first conductive layer CE1a, a second conductive layer CE1b, a third conductive layer CE1c, and a fourth conductive layer CE1d. However, the embodiments of the present disclosure are not limited thereto. More or less conductive layers may be included. For example, the first electrode CE1 may be made of one conductive layer.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, each of the first conductive layer CE1a, the second conductive layer CE1b, the third conductive layer CE1c, and the fourth conductive layer CE1d may be made of titanium (Ti), molybdenum (Mo), aluminum (Al), or indium tin oxide (ITO). However, the embodiments of the present disclosure are not limited thereto.

According to the present disclosure, some of the conductive layers having good reflection efficiency among the plurality of conductive layers constituting the first electrode CE1 can act as an alignment key for aligning the light-emitting element ED and/or a reflecting plate. For example, the second conductive layer CE1b among the plurality of conductive layers of the first electrode CE1 may include a reflective material. For example, the second conductive layer CE1b may include aluminum (Al). However, embodiments of the present disclosure are not limited thereto. Accordingly, the second conductive layer CE1b can act as the reflecting plate. In addition, due to the high reflection efficiency of the second conductive layer CE1b, it can be easily identified during the manufacturing process, and thus the position or transfer position of the light-emitting element ED can be aligned based on the second conductive layer CE1b.

For example, in order to form the second conductive layer CE1b as the reflecting plate, the third conductive layer CE1c and the fourth conductive layer CE1d covering the second conductive layer CE1b may be partially removed or etched. For example, a portion of the third conductive layer CE1c and the fourth conductive layer CE1d disposed on the bank BNK may be removed or etched to expose the upper surface of the second conductive layer CE1b. For example, the openings of the third conductive layer CE1c and the fourth conductive layer CE1d may overlap with a portion of the upper surface of the second conductive layer CE1b. For example, the central portion and the border portion or edge portion of the third conductive layer CE1c and the fourth conductive layer CE1d may be left, and the remaining portion excluding this portion (e.g., the central portion and the border portion or edge portion) may be removed, wherein the solder pattern SDP is placed on the central portion. For example, the border portion or edge portion of each of the third conductive layer CE1c made of titanium (Ti) and the fourth conductive layer CE1d made of indium tin oxide (ITO) may not be etched. Accordingly, it is possible to prevent or alleviate other conductive layers of the first electrode CE1 from being corroded by the tetramethylammonium hydroxide (TMAH) solution used in the mask process of the first electrode CE1.

According to the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which has good adhesion to the solder pattern SDP and has corrosion resistance and acid resistance. However, the embodiments of the present disclosure are not limited thereto.

The first conductive layer CE1a, the second conductive layer CE1b, the third conductive layer CE1c, and the fourth conductive layer CE1d can be sequentially deposited and then patterned by performing a photolithography process and an etching process. However, the embodiments of the present disclosure are not limited thereto.

According to the present disclosure, the signal line TL, the contact electrode CCE, and the pad electrode PE disposed on the same layer as the first electrode CE1 may be configured in a multi-layer structure of conductive materials. However, the embodiments of the present disclosure are not limited thereto. For example, the signal line TL, contact electrode CCE, and pad electrode PE may be formed in a multi-layer structure of indium tin oxide (ITO)/titanium (Ti)/aluminum (Al)/titanium (Ti). However, the embodiments of the present disclosure are not limited thereto. For example, the signal line TL, the contact electrode CCE, and the pad electrode PE disposed on the same layer as the first electrode CE1 may be configured in a single layer structure of conductive materials.

According to the present disclosure, the solder pattern SDP may be disposed on the first electrode CE1 in each of the plurality of sub-pixels. A solder pattern SDP may bond the light-emitting element ED to the first electrode CE1. The first electrode CE1 and the light-emitting element ED may be electrically connected through eutectic bonding using the solder pattern SDP. However, the embodiments of the present disclosure are not limited thereto. For example, in a case where the solder pattern SDP is made of indium (In) and the anode electrode (134) of the light-emitting element ED is made of gold (Au), the solder pattern SDP and the anode electrode 134 may be joined by applying heat and pressure during the transfer process of the light-emitting element ED. Through the eutectic bonding, the light-emitting element ED can be bonded to the solder pattern SDP and the first electrode CE1 without a separate adhesive material. For example, the solder pattern SDP may be made of indium (In), tin (Sn) or alloys thereof. However, embodiments of the present disclosure are not limited thereto. For example, the solder pattern SDP may be a bonding pad or a joining pad. However, the embodiments of the present disclosure are not limited thereto.

According to the present disclosure, a passivation layer 116 may be disposed on the plurality of signal lines TL, the plurality of first electrodes CE1, the plurality of contact electrodes CCE, and the third insulating layer 115c. For example, the passivation layer 116 may be disposed in the display area AA, the first non-display area NA1, and the second non-display area NA2. A portion of the passivation layer 116 disposed in the bending area BA may be removed. A portion of the passivation layer 116 covering the plurality of pad electrodes PE in the second non-display area NA2 may be removed. Since the passivation layer 116 is disposed to cover the remaining area except the bending area BA, the plurality of pad electrodes PE, and the area where the solder pattern SDP is disposed, the penetration of moisture or impurities into the light-emitting element ED can be reduced. For example, the passivation layer 116 may be configured in a single-layer or multi-layer structure of silicon oxide (SiOx) or silicon nitride (SiNx). However, the embodiments of the present disclosure are not limited thereto. For example, the passivation layer 116 may be a protective layer or an insulating layer. However, the embodiments of the present disclosure are not limited thereto. For example, the passivation layer 116 may include a hole through which the solder pattern SDP is exposed. For example, the hole of the passivation layer 116 may overlap with the solder pattern SDP.

In each of the plurality of sub-pixels, the light-emitting element ED may be disposed on the solder pattern SDP. Each of the first light-emitting element 130, the second light-emitting element 140 and the third light-emitting element 150 may be disposed in each of the first sub-pixel SP1, the second sub-pixel SP2 and the third sub-pixel SP3, without being limited thereto. In the first sub-pixel SP1 the first light-emitting element 130 may be disposed. In the second sub-pixel SP2 the second light-emitting element 140 may be disposed. In the third sub-pixel SP3 the third light-emitting element 150 may be disposed.

The light-emitting element ED may be formed on a silicon wafer by a method such as Metal Organic Chemical Vapor Deposition (MOCVD), Chemical Vapor Deposition (CVD), Plasma-Enhanced Chemical Vapor Deposition (PECVD), Molecular Beam Epitaxy (MBE), Hydride Vapor Phase Epitaxy (HVPE), sputtering, or the like. However, the embodiments of the present disclosure are not limited thereto.

Referring to FIG. 9, the first light-emitting element 130 may include the anode electrode 134, a first semiconductor layer 131, an active layer 132, a second semiconductor layer 133, a cathode electrode 135, and a encapsulation film 136. However, the embodiments of the present disclosure are not limited thereto. For example, the first light-emitting element 130 may not include the encapsulation film 136.

The first semiconductor layer 131 may be disposed on a solder pattern SDP. The second semiconductor layer 133 may be disposed on the first semiconductor layer 131. For example, the active layer 132 may be disposed on the first semiconductor layer 131, and the second semiconductor layer 133 may be disposed on the active layer 132.

For example, one of the first semiconductor layer 131 and the second semiconductor layer 133 may be made of a compound semiconductor of group III-V, group II-VI, or the like, and may be doped with an impurity or dopant. For example, one of the first semiconductor layer 131 and the second semiconductor layer 133 may be a semiconductor layer doped with an n-type impurity, and the other thereof may be a semiconductor layer doped with a p-type impurity. However, the embodiments of the present disclosure are not limited thereto. For example, one of the first semiconductor layer 131 and the second semiconductor layer 133 may be a layer where an n-type or p-type impurity is doped in a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs). However, the embodiments of the present disclosure are not limited thereto. For example, the n-type impurity may be silicon (Si), germanium (Ge), selenium (Se), carbon (C), tellurium (Te), tin (Sn), or the like. However, the embodiments of the present disclosure are not limited thereto. For example, the p-type impurity may be magnesium (Mg), zinc (Zn), calcium (Ca), strontium (Sr), barium (Ba), beryllium (Be), or the like. However, the embodiments of the present disclosure are not limited thereto.

As one example, the first semiconductor layer 131 and the second semiconductor layer 133 may be a nitride semiconductor, without being limited thereto. For example, the first semiconductor layer 131 and the second semiconductor layer 133 may be a nitride semiconductor containing an n-type impurity and a nitride semiconductor containing a p-type impurity, respectively. However, the embodiments of the present disclosure are not limited thereto. For example, the first semiconductor layer 131 may be a nitride semiconductor containing a p-type impurity, and the second semiconductor layer 133 may be a nitride semiconductor containing an n-type impurity. However, the embodiments of the present disclosure are not limited thereto.

The active layer 132 may be disposed between the first semiconductor layer 131 and the second semiconductor layer 133. The active layer 132 may receive holes and electrons from the first semiconductor layer 131 and the second semiconductor layer 133 to emit light. For example, the active layer 132 may be composed of one of a single well structure, a multi-well structure, a single quantum well structure, a multi-quantum well (MQW) structure, a quantum dot structure, and a quantum wiring structure. However, the embodiments of the present disclosure are not limited thereto. For example, the active layer 132 may be made of indium gallium nitride (InGaN) or gallium nitride (GaN). However, the embodiments of the present disclosure are not limited thereto.

In another example, the active layer 132 may include a multi-quantum well (MQW) structure having a well layer and a barrier layer having a higher band gap than the well layer. For example, the active layer 132 may include a InGaN layer as a well layer and an AlGaN layer as a barrier layer. However, the embodiments of the present disclosure are not limited thereto.

The anode electrode 134 may be disposed between the first semiconductor layer 131 and the solder pattern SDP. For example, the anode electrode 134 may electrically connect the first semiconductor layer 131 with the first electrode CE1. The anode voltage output from the pixel driving circuit PD may be applied to the first semiconductor layer 131 through the signal line TL, the first electrode CE1, and the anode electrode 134. For example, the anode electrode 134 may be made of a conductive material capable of eutectic bonding with the solder pattern SDP. However, the embodiments of the present disclosure are not limited thereto. For example, the anode electrode 134 may be made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or any alloy thereof. However, the embodiments of the present disclosure are not limited thereto.

The cathode electrode 135 may be disposed on the second semiconductor layer 133. For example, the cathode electrode 135 may electrically connect the second semiconductor layer 133 with the second electrode CE2. The cathode voltage output from the pixel driving circuit PD may be applied to the second semiconductor layer 133 through the contact electrode CCE, the second electrode CE2, and the cathode electrode 135. The cathode electrode 135 may be made of a transparent conductive material so that light emitted from the light-emitting element ED can be directed upwards from the light-emitting element ED. However, the embodiments of the present disclosure are not limited thereto. For example, the cathode electrode 135 may be made of a material such as indium tin oxide (ITO), indium zinc oxide (IZO), indium gallium zinc oxide (IGZO), or the like. However, the embodiments of the present disclosure are not limited thereto.

The encapsulation film 136 may be disposed on at least a portion of the first semiconductor layer 131, the active layer 132, the second semiconductor layer 133, the anode electrode 134, and the cathode electrode 135. For example, the encapsulation film 136 may surround at least a portion of the first semiconductor layer 131, the active layer 132, the second semiconductor layer 133, the anode electrode 134, and the cathode electrode 135, without being limited thereto. For example, the encapsulation film 136 may not be included in the light-emitting element ED.

For example, the encapsulation film 136 may protect the first semiconductor layer 131, the active layer 132, and the second semiconductor layer 133. For example, the encapsulation film 136 may be disposed on the side surface of the first semiconductor layer 131, the side surface of the active layer 132, and the side surface of the second semiconductor layer 133. For example, the encapsulation film 136 may surround the side surface of the first semiconductor layer 131, the side surface of the active layer 132, and the side surface of the second semiconductor layer 133.

For example, the encapsulation film 136 may be disposed on at least a portion of the anode electrode 134 and the cathode electrode 135, for example, an edge portion or a border portion or one side of the anode electrode 134 and an edge portion or a border portion or one side of the cathode electrode 135. For example, the encapsulation film 136 may surround an edge portion or a border portion or one side of the anode electrode 134 and an edge portion or a border portion or one side of the cathode electrode 135. At least a portion of the anode electrode 134 may be exposed from the encapsulation film 136 so that the anode electrode 134 and the solder pattern SDP can be connected to each other. For example, at least a portion of the cathode electrode 135 may be exposed from the encapsulation film 136 so that the cathode electrode 135 and the second electrode CE2 can be connected to each other. For example, the encapsulation film 136 may be made of an insulating material such as silicon nitride (SiNx) or silicon oxide (SiOx). However, the embodiments of the present disclosure are not limited thereto.

In another example, the encapsulation film 136 may be composed of a resin layer in which a reflective material is dispersed. However, the embodiments of the present disclosure are not limited thereto. For example, the encapsulation film 136 may be manufactured as a reflector having various structures. However, the embodiments of the present disclosure are not limited thereto. Light emitted from the active layer 132 can be reflected upward by the encapsulation film 136, so that light extraction efficiency can be improved. For example, the encapsulation film 136 may be a reflective layer. However, the embodiments of the present disclosure are not limited thereto.

According to the present disclosure, the light-emitting element ED is described as having a vertical structure. However, the embodiments of the present disclosure are not limited thereto. For example, the light-emitting element ED may have a lateral structure or a flip chip structure.

Although the first light-emitting element 130 has been described with reference to FIG. 9, the second light-emitting element 140 and the third light-emitting element 150 may have structures substantially identical or similar to that of the first light-emitting element 130. For example, the second light-emitting element 140 and the third light-emitting element 150 may include layers substantially identical to or similar to the first semiconductor layer 131, the active layer 132, the second semiconductor layer 133, the anode electrode 134, the cathode electrode 135, and the encapsulation film 136 of the first light-emitting element 130. However, the embodiments of the present disclosure are not limited thereto.

According to the present disclosure, a first optical layer 117a surrounding a plurality of light-emitting elements ED may be disposed in the display area AA. For example, the first optical layer 117a may be disposed to cover a plurality of light-emitting elements ED and banks BNK in the areas of a plurality of sub-pixels. For example, the first optical layer 117a may cover the bank BNK, a portion of the passivation layer 116, and side surfaces of a plurality of light-emitting elements ED. The first optical layer 117a may cover or be disposed in an area between a plurality of light-emitting elements ED and between a plurality of banks BNK included in one pixel PX. For example, the first optical layers 117a may extend in a first direction and be spaced apart from each other in the second direction. For example, the first optical layer 117a may be disposed between the passivation layer 116 and the second electrode CE2 to surround the side portions of the light-emitting element ED and the bank BNK. However, the embodiments of the present disclosure are not limited thereto. For example, the first optical layer 117a may be a diffusion layer or a sidewall diffusion layer. However, the embodiments of the present disclosure are not limited thereto.

The first optical layer 117a may include an organic insulating material having fine particles dispersed therein. However, the embodiments of the present disclosure are not limited thereto. For example, the first optical layer 117a may be made of siloxane in which fine metal particles such as titanium dioxide (TiO₂) particles are dispersed. However, the embodiments of the present disclosure are not limited thereto. Light from the plurality of light-emitting elements ED may be scattered by fine particles dispersed in the first optical layer 117a and emitted to the outside of the display device 1000. Accordingly, the first optical layer 117a can improve the extraction efficiency of light emitted from the plurality of light-emitting elements ED.

For example, the first optical layer 117a may be disposed in each of the plurality of pixels PX, or may be disposed commonly in some of the pixels PX disposed in the same row. However, the embodiments of the present disclosure are not limited thereto. For example, the first optical layer 117a may be disposed in each of a plurality of pixels PX, or a plurality of pixels PX may share one first optical layer 117a. However, the embodiments of the present disclosure are not limited thereto. In another example, each of the plurality of sub-pixels may separately include a first optical layer 117a. However, the embodiments of the present disclosure are not limited thereto.

According to the present disclosure, a second optical layer 117b may be disposed on the passivation layer 116 in the display area AA. For example, the second optical layer 117b may be disposed to surround the first optical layer 117a. For example, the second optical layer 117b may be in contact with a side surface of the first optical layer 117a. For example, the second optical layer 117b may be disposed in an area between adjacent ones of a plurality of pixels PX. However, the embodiments of the present disclosure are not limited thereto. For example, the second optical layer 117b may be a diffusion layer, a diffusion layer window, a window diffusion layer, or the like. However, the embodiments of the present disclosure are not limited thereto.

The second optical layer 117b may be made of an organic insulating material. However, the embodiments of the present disclosure are not limited thereto. The second optical layer 117b may be made of the same material as the first optical layer 117a. However, the embodiments of the present disclosure are not limited thereto. For example, the second optical layer 117b may be composed of the different material from the first optical layer 117a. For example, the first optical layer 117a may include fine particles, and the second optical layer 117b may not include fine particles. For example, the second optical layer 117b may be made of siloxane. However, the embodiments of the present disclosure are not limited thereto.

For example, the thickness of the first optical layer 117a may be smaller than the thickness of the second optical layer 117b. However, the embodiments of the present disclosure are not limited thereto. Accordingly, when viewed in a cross-sectional view of the display device 1000, the first optical layer 117a may include a concave portion that is recessed inward more than the upper surface of the second optical layer 117b.

According to the present disclosure, the second electrode CE2 may be disposed on the first optical layer 117a and the second optical layer 117b. For example, the second electrode CE2 may be electrically connected to the plurality of contact electrodes CCE through contact holes in the second optical layer 117b. For example, the second electrode CE2 may be disposed on a plurality of light-emitting elements ED. For example, the second electrode CE2 may include a transparent conductive oxide such as indium tin oxide (ITO) or indium zinc oxide (IZO). However, the embodiments of the present disclosure are not limited thereto. For example, the second electrode CE2 may be disposed in contact with the cathode electrode 135. For example, the second electrode CE2 may overlap with the first optical layer 117a. For example, the second electrode CE2 may cover the upper surface of the first optical layer 117a.

The second electrode CE2 may extend continuously in the first direction of the substrate 110. Accordingly, the second electrode CE2 can be commonly connected to a plurality of pixels PX arranged in the first direction of the substrate 110. For example, the second electrode CE2 may be commonly connected to a plurality of pixels PX.

According to the present disclosure, the second electrode CE2 may extend continuously over the first optical layer 117a, the second optical layer 117b, and the light-emitting element ED. The first optical layer 117a may include a concave portion that is recessed inward more than the upper surface of the second optical layer 117b. Accordingly, a first portion of the second electrode CE2 disposed on the first optical layer 117a is disposed along the concave portion, and thus can be disposed at a lower position than a second portion of the second electrode CE2 disposed on the second optical layer 117b.

A third optical layer 117c may be disposed on the second electrode CE2. The third optical layer 117c may be disposed to overlap with the plurality of light-emitting elements ED and the first optical layer 117a. Since the third optical layer 117c is disposed on the second electrode CE2 and the plurality of light-emitting elements ED, a mura that may occur on some of the plurality of light-emitting elements ED may be alleviated. For example, when transferring the plurality of light-emitting elements ED onto the substrate 110 of the display device 1000, its process deviation or the like may cause the occurrence of an area where the spacings between the plurality of light-emitting elements ED are not uniform. If the spacings between the plurality of light-emitting elements ED are not uniform, the light emission areas of the plurality of respective light-emitting elements ED may be disposed unevenly, which may cause the mura to be visible to the user. Accordingly, since the third optical layer 117c configured to uniformly diffuse light is disposed on top of the plurality of light-emitting elements ED, it is possible to alleviate the phenomenon in which light emitted from some light-emitting elements ED looks like mura. Accordingly, since the light emitted from the plurality of light-emitting elements ED is evenly diffused by the third optical layer 117c and extracted to the outside of the display device 1000, the luminance uniformity of the display device 1000 can be improved.

For example, the third optical layer 117c may be made of the same material as the first optical layer 117a. The third optical layer 117c may be made of an organic insulating material having fine particles dispersed therein. However, the embodiments of the present disclosure are not limited thereto. For example, the third optical layer 117c may be made of siloxane in which fine particles such as titanium dioxide (TiO₂) particles dispersed. However, the embodiments of the present disclosure are not limited thereto. However, the embodiments of the present disclosure are not limited thereto. The third optical layer 117c may be composed of the different material from the first optical layer 117a, but the embodiments of the present disclosure are not limited thereto. For example, the third optical layer 117c may be an upper side diffusion layer or an upper surface diffusion layer. However, the embodiments of the present disclosure are not limited thereto.

According to the present disclosure, light from a plurality of light-emitting elements ED can be scattered by fine particles dispersed in the third optical layer 117c and be emitted to the outside of the display device 1000. The third optical layer 117c can evenly mix the lights emitted from the plurality of light-emitting elements ED to further improve the luminance uniformity of the display device 1000. Furthermore, the light extraction efficiency of the display device 1000 can be improved by the light being scattered by the plurality of fine particles, thereby enabling the display device 1000 to be driven at low power.

A black matrix BM may be disposed on the second electrode CE2, the first optical layer 117a, the second optical layer 117b, and the third optical layer 117c in the display area AA. For example, the black matrix BM may be configured to cover the second electrode CE2, the first optical layer 117a, the second optical layer 117b, and the third optical layer 117c in the display area AA. For example, the black matrix BM may fill the contact hole in the second optical layer 117b. The black matrix BM may be disposed to cover the display area AA, so that color mixing of light from a plurality of sub-pixels and external light reflection can be reduced. For example, since the black matrix BM may be disposed within the contact hole where the second electrode CE2 and the contact electrode CCE are connected to each other, light leakage between neighboring sub-pixels can be prevented.

For example, the black matrix BM may be made of an opaque material. However, the embodiments of the present disclosure are not limited thereto. For example, the black matrix BM may be made of an organic insulating material having black pigment or black dye added thereto. However, the embodiments of the present disclosure are not limited thereto.

A cover layer 118 may be disposed on the black matrix BM in the display area AA. For example, the cover layer 118 may be configured to cover the components under the cover layer 118. The cover layer 118 can protect the components under the cover layer 118. For example, the cover layer 118 may be made of an organic insulating material. However, the embodiments of the present disclosure are not limited thereto. For example, the cover layer 118 may be made of a photoresist, polyimide (PI), or photo acryl-based material, or the like. However, the embodiments of the present disclosure are not limited thereto. For example, the cover layer 118 may be an overcoat layer or an insulating layer. However, the embodiments of the present disclosure are not limited thereto.

The polarizing layer 293 may be disposed on the cover layer 118 via a first adhesive layer 291. For example, the polarizing layer 293 may be configured to cover the cover layer the first adhesive layer 291, and the first adhesive layer 291 may be configured to cover the cover layer 118. The cover member 155 may be disposed on the polarizing layer 293 via a second adhesive layer 295. For example, the first adhesive layer 291 and the second adhesive layer 295 may include an optically clear adhesive (OCA), an optically clear resin (OCR), or a pressure sensitive adhesive (PSA). However, the embodiments of the present disclosure are not limited thereto.

According to the present disclosure, the plurality of pad electrodes PE may be disposed on the third insulating layer 115c in the second non-display area NA2. For example, at least a portion of the plurality of pad electrodes PE may be exposed from the passivation layer 116. For example, a plurality of pad electrodes PE may be electrically connected to the (2-4)-th connection line 122d through the contact hole in the third insulating layer 115c.

An adhesive layer ACF may be disposed on the plurality of pad electrodes PE. For example, the adhesive layer ACF may be configured to cover the plurality of pad electrodes PE. The adhesive layer ACF may be an adhesive layer in which conductive balls are dispersed in an insulating material. However, the embodiments of the present disclosure are not limited thereto. In a case where heat or pressure is applied to the adhesive layer ACF, the conductive balls can be electrically connected in the part where the heat or pressure is applied, thereby providing conductive property. By placing the adhesive layer ACF between a plurality of pad electrodes PE and the flexible circuit board (or flexible film) 157, the flexible circuit board (or flexible film) 157 can be attached or bonded to a plurality of pad electrodes PE. For example, the adhesive layer ACF may be an anisotropic conductive film. However, the embodiments of the present disclosure are not limited thereto.

The adhesive layer ACF may be disposed on the plurality of pad electrodes PE and the flexible circuit board (or flexible film) 157 may be disposed on the adhesive layer ACF. For example, the flexible circuit board (or flexible film) 157 may be configured to cover the adhesive layer ACF. The flexible circuit board (or flexible film) 157 may be electrically connected to the plurality of pad electrodes PE through the adhesive layer ACF. Accordingly, signals output from the flexible circuit board (or flexible film) 157 and the printed circuit board can be transmitted to the pixel driving circuit PD in the display area AA through the plurality of pad electrodes PE, the (2-4)-th connection line 122d, the (2-3)-th connection line 122c, the (2-2)-th connection line 122b, and the (2-1)-th connection line 122a.

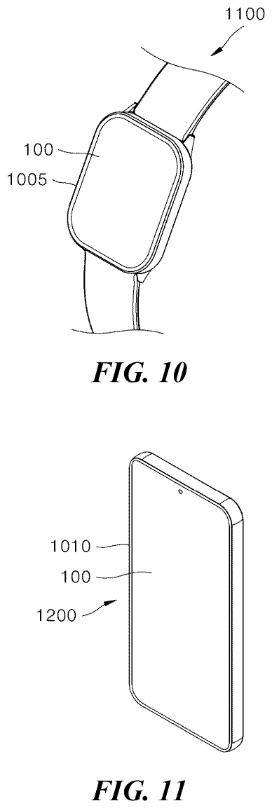

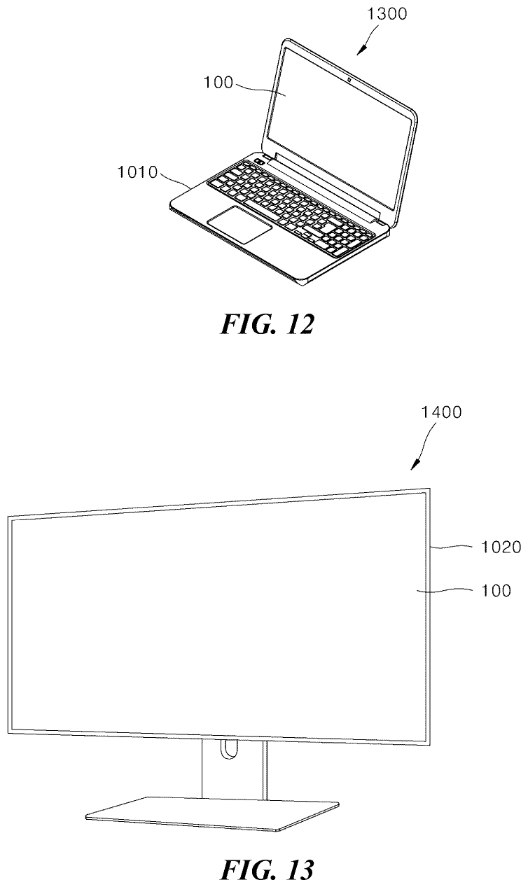

FIGS. 10 to 13 are views illustrating devices to which display devices according to embodiments of the present disclosure are applied.

Referring to FIGS. 10 to 13, the display device 1000 according to the embodiments of the present disclosure may be included in various devices or electronic devices. For example, referring to FIGS. 10 to 13, various electronic devices may include a wearable device 1100, a mobile device 1200, a notebook 1300, and a monitor or TV 1400. However, the embodiments of the present disclosure are not limited thereto.

Each of the wearable device 1100, the mobile device 1200, the notebook 1300, and the monitor or TV 1400 may include a case 1005, 1010, 1015, 1020, the display panel 100 and the display device 1000 according to the exemplary embodiment of the present disclosure described with reference to FIGS. 1 to 9.

For example, the display device according to the exemplary embodiment of the present disclosure may be applied to a mobile device, a video phone, a smart watch, a watch phone, a wearable device, a foldable device, a rollable device, a bendable device, a flexible device, a curved device, a sliding device, a variable device, an electronic notebook, an electronic book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a notebook, a monitor, a camera, a camcorder, home appliances, or the like.

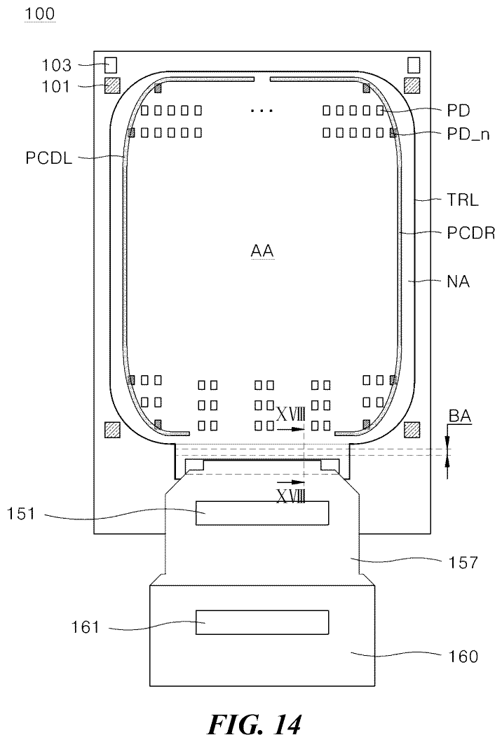

FIG. 14 is a plan view of a display panel according to an exemplary embodiment of the present disclosure.

Referring to FIG. 14, the flexible circuit board 157 and the printed circuit board 160 may be connected to one side of the display panel 100. The flexible circuit board 157 and the printed circuit board 160 may be disposed at least on one side edge of the display panel 100. For example, the flexible circuit board 157 and the printed circuit board 160 may be disposed at a lower portion of the display panel 100. One side of the flexible circuit board 157 may be attached to the display panel 100, and the other side thereof may be attached to the printed circuit board 160. The flexible circuit board 157 may be a flexible film, but the embodiments of the present disclosure are not limited thereto.

The flexible circuit board 157 may be a film in which various components are arranged on a flexible base film. For example, the driving IC such as a gate driver IC or a data driver IC may be arranged on one or more flexible circuit board 157, but the embodiments of the present disclosure are not limited thereto.

The flexible circuit board 157 may provide power or signals supplied from the printed circuit board 160 to a plurality of pixel driving circuits of the display panel 100.

The flexible circuit board 157 may include a control circuit, which is a timing controller 151. The printed circuit board 160 may include a power management integrated circuit 161.

The display panel 100 may include a display area AA where an image is displayed and a non-display area NA where an image is not displayed. The display panel 100 may include a trimming line TRL along an outer edge of the non-display area NA. The trimming line TRL may refer to an area cut by a laser during a scribing process to separate a plurality of individual unit display panels 100 from a mother substrate. An area located outside the trimming line TRL may be removed through the scribing process.

In the display area AA a plurality of driving chips PD and a plurality of pixels including a plurality of light-emitting elements electrically connected to the plurality of driving chips PD may be arranged. Each driving chip PD may control the light-emitting operation of the plurality of light-emitting elements by supplying control signals and power to the plurality of light-emitting elements. Each driving chip PD may be a micro driver, without being limited thereto. For example, each of the driving chips PD may control the light-emitting operation of each of the plurality of light-emitting elements by supplying control signals and power to the plurality of light-emitting elements.

The display panel 100 may have a shape whose one side is longer than another side thereof. For example, the display panel 100 may include a long side and a short side that is shorter than the long side.

The display panel 100 may include one or more crack detection lines PCDL, PCDR disposed in a portion of the non-display area NA. Each of one or more crack detection lines PCDL, PCDR may be disposed along the outer part of the display area AA to detect defects such as cracks that may occur in the outer part of the display area AA. One or more crack detection lines PCDL, PCDR may be disposed to surround at least a portion of both side areas, upper and lower areas of the display area AA. For example, the one or more crack detection lines PCDL, PCDR may include a first crack detection line PCDL and a second crack detection line PCDR.

For example, the first crack detection line PCDL may be disposed to surround one side area of the display area AA and at least a portion of upper and lower areas of the display area AA, and the second crack detection line PCDR may be disposed to surround another side area of the display area AA and at least a portion of upper and lower areas of the display area AA, without being limited thereto.

The first crack detection line PCDL may extend along a left long side of the display panel 100 and may extend to each of upper and lower left corners of the display panel 100 and then may extend along a left portion of each of upper and lower short sides of the display panel 100. The second crack detection line PCDR may extend along a right long side of display panel 100 and may extend to each of upper and lower right corners of the display panel 100 and then may extend along a right portion of each of the upper and lower short sides of the display panel 100. The first crack detection line PCDL and the second crack detection line PCDR may be disposed spaced apart from each other, without being limited thereto.

The first crack detection line PCDL and the second crack detection line PCDR can be disposed to overlap with some driving chips of the plurality of driving chips PD at the corner area of the display panel 100. The driving chip disposed to overlap with the first and second crack detection lines PCDL, PCDR at the corner area may be an inactive driving chip PD_n.

Each of the driving chips PD arranged in the display area AA may be an active driving chip capable of supplying control signals and power to a plurality of light-emitting elements to control light-emitting operations of the plurality of light-emitting elements. In order for each driving chip PD to control the plurality of light-emitting elements, not only power line but also signal line for controlling the on/off or light-emitting time of the light-emitting elements are required.

The inactive driving chip PD_n may not be electrically connected to at least some of the power lines or the signal lines as it is disposed to overlap with the first crack detection line PCDL or the second crack detection line PCDR at the corner area of the display panel 100. Accordingly, the inactive driving chip PD_n may be an unused driving chip that cannot control the plurality of light-emitting elements. Eight inactive driving chips PD_n may be positioned along the corner areas of the display panel 100, without being limited thereto.

In the outer side of the trimming line TRL a plurality of alignment key patterns 101, 103 may be disposed. The plurality of alignment key patterns 101, 103 may include a first sort key pattern 101 and a second sort key pattern 103. However, the embodiments of the present disclosure are not limited thereto.

The first alignment key pattern 101 may be a pattern for alignment between the display panel 100 and the cover member 155 of FIG. 1. A plurality of first alignment key patterns 101 may be positioned with at least one at each outer side area of the trimming line TRL facing each corner area of the display panel 100. For example, the plurality of first alignment key patterns 101 may be comprised of four alignment key patterns, each being disposed at a respective one of four corner areas of the display panel 100.

The second alignment key pattern 103 may include various alignment key patterns for aligning components disposed in different layers, such as a plurality of signal lines, contact holes, and a plurality of driving chips disposed on the display panel 100, to the correct positions. The second alignment key pattern 103 may include a metal material. Accordingly, the second alignment key pattern 103 may be disposed in the display area AA or the non-display area NAA, and be formed together with a plurality of signal lines including a metal material. However, embodiments of the present disclosure are not limited thereto.

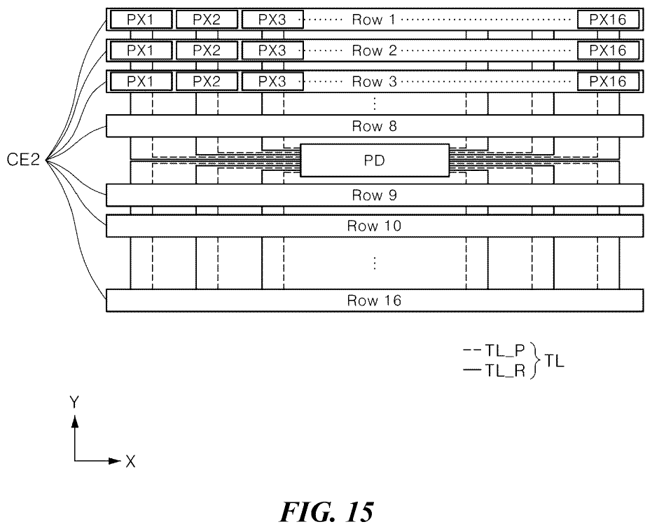

FIG. 15 is a plan view showing an area where one of the plurality of driving chips of FIG. 14 is disposed.

Referring to FIG. 15, the plurality of driving chips PD may be arranged in a matrix shape in the display area AA. On one driving chip PD, a plurality of pixels PX1 to PX16 including a plurality of light-emitting elements may be arranged in a matrix shape. A plurality of pixels may be arranged to be spaced apart from each other in a first direction and a second direction intersecting the first direction. The first direction may be the X-axis direction of the display panel 100, and the second direction may be the Y-axis direction of the display panel 100. However, the exemplary embodiment of the present disclosure is not limited thereto. For example, the first direction may be the horizontal direction or row direction of the display panel 100, and the second direction may be the vertical direction or column direction of the display panel 100.

The sub-pixels emitting the light of different colors may be disposed in the first direction of the display panel 100. In the first direction of the display panel 100, sub-pixels emitting light of different colors may be disposed alternately, without being limited thereto. Additionally, sub-pixels emitting light of the same color may be disposed in the second direction of the display panel 100. In the second direction of the display panel 100, sub-pixels emitting the light of same color may be disposed alternately, without being limited thereto. For example, the first pixel PX1 to the sixteenth pixel PX16 may be arranged in the row direction, which is the first direction. A single pixel PX may include red R, green G, and blue B sub-pixels, without being limited thereto. For example, white sub-pixel, cyan sub-pixel, magenta sub-pixel, or yellow sub-pixel, etc., are also possible. Accordingly, in the first direction, which is the row direction, for example, the sub-pixels of red R, green G, and blue B may be disposed in a repeating order.

A plurality of light-emitting elements may be disposed corresponding to each sub-pixel. At least one light-emitting element may be disposed in one sub-pixel. For example, two light-emitting elements may be disposed in one sub-pixel. One of the two light-emitting elements may be a main light-emitting element and the other thereof may be a redundant light-emitting element. The light-emitting element may be a micro LED.

Additionally, sub-pixels emitting the light of same color may be disposed in the second direction, for example, the column direction. For example, sub-pixels of one color among red R, green G, or blue B can be disposed in the second direction, for example, the column direction. Sub-pixels emitting the light of same color may be electrically connected to each other via one signal line TL_P or TL_R.

The signal line TL may include a main line TL_P and a redundancy line TL_R. The main line TL_P and the redundancy line TL_R may be disposed spaced apart from each other in the first direction of the display panel 100. The main line TL_P may be connected to the main light-emitting element through the first electrode CE1, and the redundancy line TL_R may be connected to the redundant light-emitting element through the first electrode CE1.

Each of the plurality of second electrodes CE2 may extend in the first direction. Additionally, each of the plurality of second electrodes CE2 may be arranged to be spaced apart from each other in the second direction. Accordingly, each second electrode CE2 can extend in the first direction to be connected to each of the first to sixteenth pixels PX1 to PX16 disposed in each of a plurality of rows Row 1, Row2, Row 3, . . . , Row 16.

One driving chip PD may include a plurality of driving circuits to drive a plurality of light-emitting elements. One driving chip PD may be connected to a plurality of second electrodes CE2 and a plurality of signal lines TL connected to a plurality of pixels PX1, PX2, . . . , PX16. For example, one driving chip PD may drive a plurality of light-emitting elements arranged on the first to sixteenth rows Row1 to Row 16. For example, the one driving chip PD may drive a plurality of light-emitting elements arranged on each of the first to sixteenth rows Row1 to Row 16. In other words, one driving chip PD may be electrically connected to a plurality of light-emitting elements arranged on the first to sixteenth rows Row1 to Row16 through a plurality of signal lines TL and a plurality of second electrodes CE2, and may control the light-emitting operations of the plurality of light-emitting elements arranged on each of the first to sixteenth rows Row1 to Row 16 by supplying control signals and power to the plurality of light-emitting elements through the plurality of signal lines TL and the plurality of second electrodes CE2.

The plurality of signal lines TL may be radially connected to the driving chip PD to connect a plurality of pixels PX1, PX2, . . . , PX16 arranged in each of the plurality of rows Row 1, Row2, Row 3, . . . , Row 16 to the driving chip PD. In this way, the driving chip PD may be configured to drive the plurality of pixels PX1, PX2, . . . , PX16 arranged in each of the plurality of rows Row 1, Row2, Row 3, . . . , Row 16. For example, when viewed from above the display panel 100, a shape in which the plurality of signal lines TL are connected to the driving chip PD may look like a rhombus shape in the area around the driving chip PD. For example, when viewed from above the display panel 100, the arrangement shape of the plurality of connection lines connecting the plurality of signal lines TL and the driving chip PD may look like a rhombus shape in the area around the pixel driving circuit PD.

The display device according to an exemplary embodiment of the present disclosure may have an in-cell touch structure that uses each of a plurality of second electrodes CE2 as a touch electrode instead of forming separate touch panel. Accordingly, the thickness of the display panel can be reduced since separate touch panel is not formed.

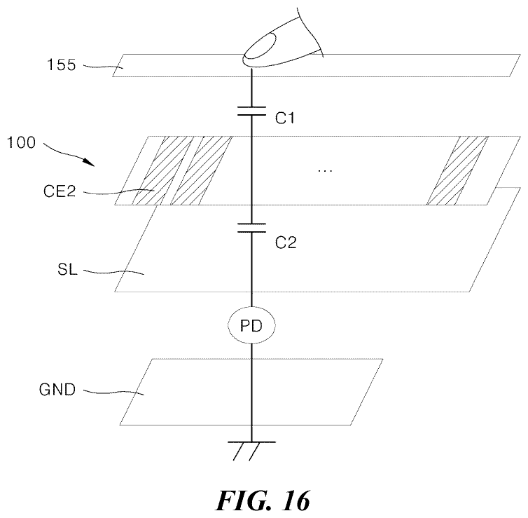

Referring to FIG. 16, when a user's touch operation is performed on the cover member 155, a change in a first capacitance C1 between the plurality of second electrodes CE2 disposed on the display panel 100 and the cover member 155, and a change in a second capacitance C2 between the plurality of second electrodes CE2 and the plurality of signal lines SL may be detected and provided to the driving chip PD. And the driving chip PD may perform a role of a touch controller to provide a control signal for operation according to the touch input to a plurality of light-emitting elements. On one side facing opposite to the cover member 155 a grounding part GND may be disposed.

The display device 1000 according to an exemplary embodiment of the present disclosure may perform touch driving and touch sensing in a self-capacitance-based touch sensing manner, or may perform touch driving and touch sensing in a mutual-capacitance-based touch sensing manner.

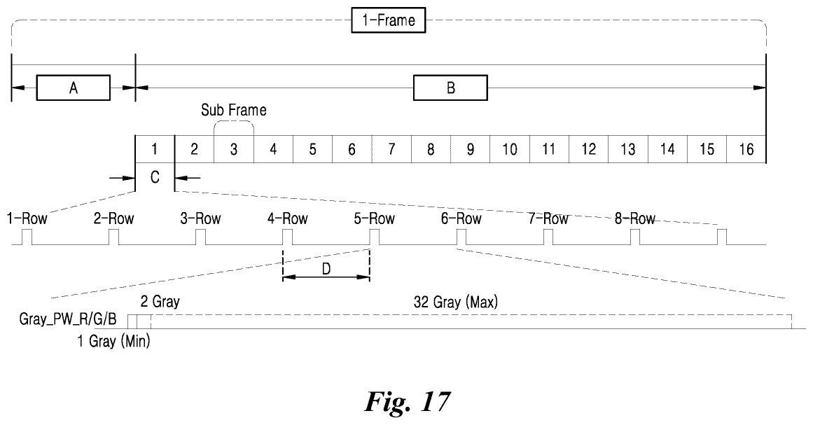

FIG. 17 illustrates an example of a signal waveform diagram when driving a display device according to an exemplary embodiment of the present disclosure.

Referring to FIG. 17, the display device according to an exemplary embodiment of the present disclosure may perform an emission operation in units of one frame.

One frame may include a touch period A and a display period B.

As one example, the touch period A may operate for a first time period at a particular frequency, and the display period B may operate for a second time period different from the first time period at the particular frequency. One frame may operate at a frequency of, for example, 60 Hz. In this case, the touch period A may operate for a first time period at a frequency of, for example, 60 Hz, and the display period B may operate for a second time period longer than the first time period at a frequency of, for example, 60 Hz. Therefore, the operation time of the touch period A and the operation time of the display period B within one frame may be different from each other. For example, the operation time of the touch period A may be shorter than the operation time of the display period B.

The display period B may include a plurality of sub-frames, such as sixteen sub-frames.

For example, in a case where eight micro LEDs are connected to each signal line connected to a driving chip in a display panel, one sub-frame period C may include eight pulse signals 1-Row, 2-Row, 3-Row, 4-Row, 5-Row, 6-Row, 7-Row, 8-Row. For example, in the exemplary embodiment of the present disclosure eight micro LEDs may operate during one sub-frame.

Therefore, in the exemplary embodiment of the present disclosure, since one frame includes sixteen sub-frames and one sub-frame includes eight pulse signals, 128 micro LEDs can operate during one frame.

The exemplary embodiment of the present disclosure is not limited thereto. For example, in a case where sixteen micro LEDs are connected to each signal line connected to the driving chip, one sub-frame period C can include sixteen pulse signals. In this case, 256 micro LEDs can operate during one frame.

One pulse signal (e.g., 5-Row) drives one micro LED. One pulse signal period D may include a high signal period and a low signal period. In this regard, the length of time of the low signal period may be greater than that of the high signal period.

In an exemplary embodiment of the present disclosure, the driving time of a micro LED may be controlled based on a light-emitting signal EM applied to a gate electrode of a light-emitting transistor T_{EM}.

The micro driver may control the application time of the light-emitting signal EM with the pulse width PW. For example, in a case where one pulse signal (e.g., 5-Row) is applied to the gate electrode of a light-emitting transistor T_{EM} with one pulse width PW, it may be called 1 Gray.

The micro driver may control the application time of the light-emitting signal EM by adjusting the pulse width PW from minimum 1 Gray to maximum 32 Gray for one pulse signal (e.g., 5-Row).

A single pixel PX may include a plurality of sub-pixels, such as red R, green G, and blue B sub-pixels, without being limited thereto. For example, white sub-pixel, cyan sub-pixel, magenta sub-pixel, or yellow sub-pixel, etc., may be also possible. Each of the plurality of micro LEDs may be disposed in each sub-pixel.

As one example, the micro driver can control the light-emitting time of the micro LED corresponding to each sub-pixel. For example, the micro driver can control the light-emitting time of the micro LED corresponding to each sub-pixel of red R, green G, or blue B by applying a pulse signal with a pulse width PW adjusted from at least 1 Gray Min to at most 32 Gray Max to the gate electrode of the light-emitting transistor T_{EM}.

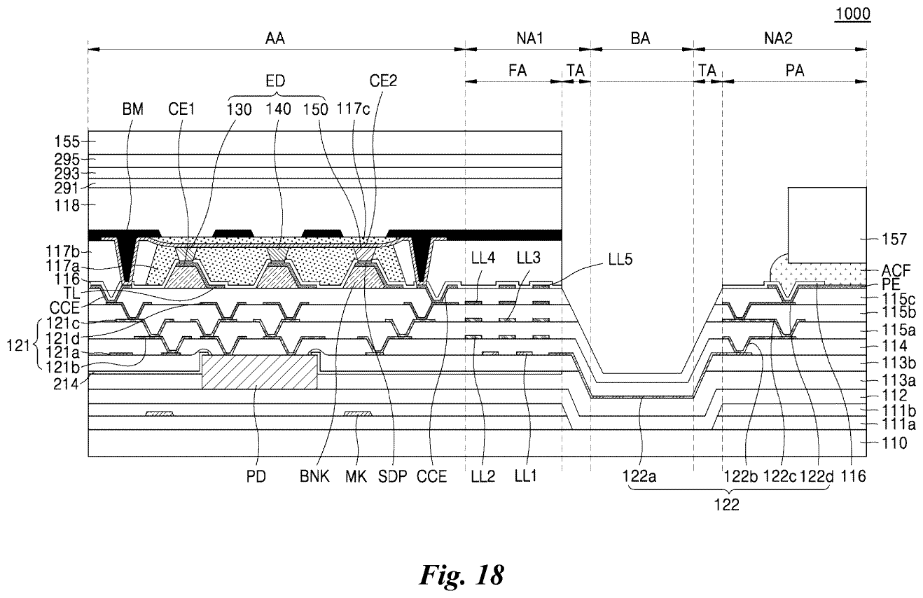

FIG. 18 is a cross-sectional view taken along line XVIII-XVIII of FIG. 14.

In FIG. 18, the same components as those described with reference to FIGS. 1 to 9 will be referred to by the same drawing reference numerals as used therein, and the description thereof will be simplified or omitted.

Referring to FIG. 18, the display panel may include a display area AA where an image is displayed and a non-display area NA where an image is not displayed, and the non-display area NA may include a first non-display area NA1, a bending area BA, and a second non-display area NA2. For example, the first non-display area NA1 may include a fan-out area FA, and a taper area TA, and the second non-display area NA2 may include a taper area TA and a pad area PA, without being limited thereto.

In the display area AA a plurality of light-emitting elements 130, 140, 150 and at least one driving chip PD electrically connected to the plurality of light-emitting elements 130, 140, 150 may be disposed. The at least one driving chip PD may be configured to drive at least one of the plurality of light-emitting elements 130, 140, 150.

The first protective layer 113a and the second protective layer 113b disposed on the adhesive layer 112 may be disposed to surround a side surface of at least one driving chip PD. However, the embodiments of the present disclosure are not limited thereto. For example, the second protective layer 113b may be disposed to cover at least a portion of the upper surface of the driving chip PD. Between the first protective layer 113a and the second protective layer 113b a protective film 214 may be disposed.

The first protective layer 113a may be disposed to cover a portion of the side surface of the driving chip PD. The protective film 214 may include a first portion disposed on the upper surface of the first protective layer 113a, a second portion disposed on the side surface of the driving chip PD, and a third portion disposed on the edge of the upper surface of the driving chip PD.

The second protective layer 113b may be disposed on the protective film 214. The second protective layer 113b may be disposed to cover the edge of the upper surface of the driving chip PD while covering the third portion of the protective film 214.

The protective film 214 can strengthen the adhesion between the driving chip PD and the second protective layer 113b to prevent or alleviate a gap from occurring between the driving chip PD and the second protective layer 113b during a subsequent process. By preventing a gap from occurring between the driving chip PD and the second protective layer 113b, it is possible to prevent or alleviate damage to the driving chip PD or sinking of the third protective layer 114 around the driving chip PD due to moisture, a chemical solution, or the like from penetrating through the gap during the manufacturing process. The protective film 214 may include an inorganic insulating material. For example, the protective film 214 may include silicon nitride (SiN).

In order to electrically connect a plurality of light-emitting elements 130, 140, 150 with a plurality of driving chips PD, a plurality of first connection lines 121 may be disposed between the plurality of light-emitting elements 130, 140, 150 and the plurality of driving chips PD. The plurality of driving chips PD may be electrically connected to the plurality of signal lines TL and the plurality of contact electrodes CCE through the plurality of first connection lines 121. For example, the plurality of first connection lines 121 may include a (1-1)-th connection line 121a, a (1-2)-th connection line 121b, a (1-3)-th connection line 121c, and a (1-4)-th connection line 121d. However, the embodiments of the present disclosure are not limited thereto.

The side surfaces of the plurality of light-emitting elements 130, 140, 150 may be covered with the sidewall diffusion layer 117a. Around the sidewall diffusion layer 117a a window diffusion layer 117b may be disposed. the sidewall diffusion layer 117a and the window diffusion layer 117b, the second electrode CE2 may be disposed on the plurality of light-emitting elements 130, 140, 150. an upper surface diffusion layer 117c may be disposed on the second electrode CE2.

The black matrix BM may be disposed on the upper surface diffusion layer 117c. The black matrix BM may be configured to cover the upper surface diffusion layer 117c. For example, the black matrix BM may be disposed on a portion of the upper surface diffusion layer 117c and the second optical layer 117b. For example, the black matrix BM may fill the contact hole in the second optical layer 117b. The cover layer 118 may be disposed on the black matrix BM and the upper surface diffusion layer 117c.

For example, the black matrix BM may be made of an opaque material. However, the embodiments of the present disclosure are not limited thereto. For example, the black matrix BM may be made of an organic insulating material having black pigment or black dye added thereto. However, the embodiments of the present disclosure are not limited thereto.

The polarizing layer 293 may be disposed on the cover layer 118 via a first adhesive layer 291. For example, the polarizing layer 293 may be configured to cover the cover layer the first adhesive layer 291, and the first adhesive layer 291 may be configured to cover the cover layer 118. On the polarizing layer 293 the cover member 155 may be disposed via a second optical adhesive layer 295.

The fan-out area FA may be an area where a plurality of link lines LL1, LL2, LL3, LL4, LL5 are disposed to connect a plurality of connection lines 121 disposed in the display area AA to the pad area PA.

The plurality of link lines LL1, LL2, LL3, LL4, LL5 may include a first link line LL1, a second link line LL2, a third link line LL3, a fourth link line LL4, and a fifth link line LL5. The first link line LL1, the second link line LL2, the third link line LL3, the fourth link line lL4, and the fifth link line LL5 may be disposed on different insulating layers from each other.

Each of the plurality of link lines LL1, LL2, LL3, LL4, LL5 may be formed together with the plurality of connection lines 121 and the plurality of signal lines TL, and be disposed on the same layer. As one example, each of the plurality of link lines LL1, LL2, LL3, LL4, LL5 may be disposed on the same layer as each of the plurality of connection lines 121. For example, the first link line LL1 may be disposed on the same layer as the (1-1)-th connection line 121a, and the second link line LL2 may be disposed on the same layer as the (1-2)-th connection line 121b. Additionally, the third link line LL3 may be disposed on the same layer as the (1-3)-th connection line 121c, and the fourth link line LL4 may be disposed on the same layer as the (1-4)-th connection line 121d. Additionally, the fifth link line LL5 may be disposed on the same layer as the signal line TL.

The first link line LL1 may extend through the bending area BA to the pad area PA. However, the embodiments of the present disclosure are not limited thereto. A portion of the first link line LL1 extended to the pad area PA may be the (2-1)-th connection line 122a. The (2-1)-th connection line 122a may be a signal connection line.

A laminated structure including the adhesive layer 112, the first protective layer 113a, the (2-1)-th connection line 122a, the third protective layer 114, and the first insulating layer 115a may be disposed on the substrate 110 in the bending area BA. A laminated structure including the adhesive layer 112, the first protective layer 113a, the second protective layer 113b, the third protective layer 114, the first insulating layer 115a, second insulating layer 115b, the third insulating layer 115c and a plurality of link lines may be disposed on the substrate 110 in the fan-out area FA. The bending area BA may have a thickness relatively smaller than that of the fan-out area FA.

The pad area PA may include the (2-2)-th connection line 122b, the (2-3)-th connection line 122c, the (2-4)-th connection line 122d, and the pad electrode PE, all of which are electrically connected to the (2-1)-th connection line 122a extending from the display area AA.

The (2-2)-th connection line 122b, the 2-3 connection line 122c, the (2-4)-th connection line 122d, and the pad electrode PE may be formed together with the plurality of connection lines 121 and a plurality of signal lines TL, and be disposed on the same layer. As one example, each of the (2-2)-th connection line 122b, the (2-3)-th connection line 122c, the (2-4)-th connection line 122d may be disposed on the same layer as each of the plurality of connection lines 121, without being limited thereto. For example, the (2-2)-th connection line 122b may be disposed on the same layer as the (1-2)-th connection line 121b. In addition, the (2-3)-th connection line 122c may be disposed on the same layer as the (1-3)-th connection line 121c, and the (2-4)-th connection line 122d may be disposed on the same layer as the (1-4)-th connection line 121d. Additionally, the pad electrode PE may be disposed on the same layer as the signal line TL.

Meanwhile, in order to prevent or alleviate the bonding properties of one or more insulating layers from being degraded and causing defects such as delamination or cracks in the bending area BA during the bending operation, the thickness of the insulating layers may be gradually reduced in the taper area TA.

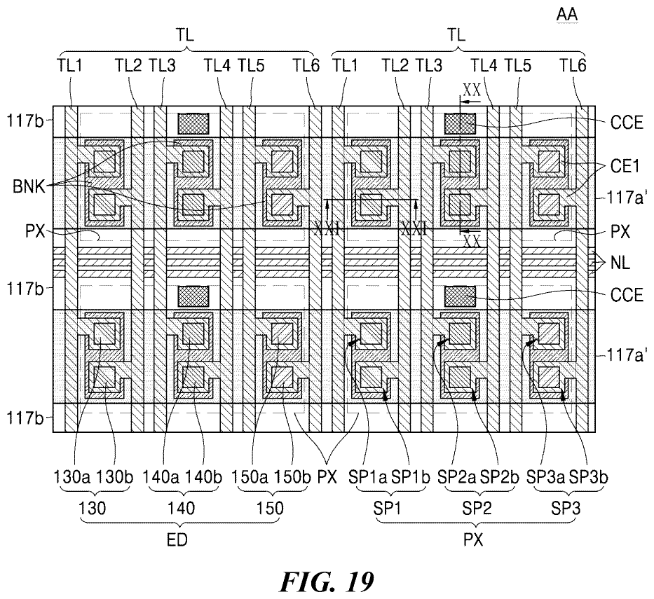

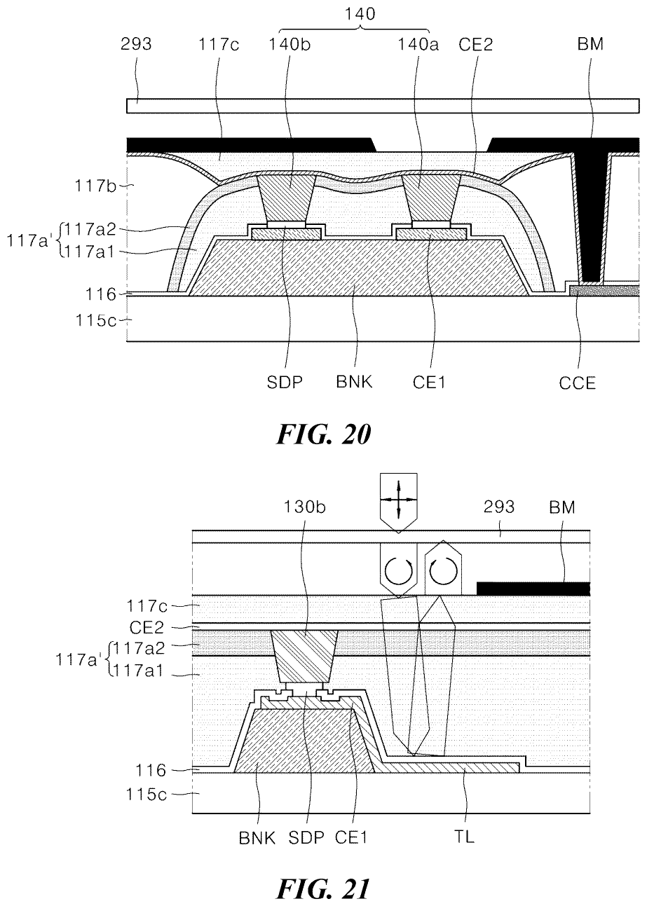

FIG. 19 is an enlarged plan view of a display area with a plurality of pixels included therein of a display device according to an exemplary embodiment of the present disclosure. FIG. 19 is similar to FIG. 5, but further illustrates a sidewall diffusion layer 117a′ and a window diffusion layer 117b. In FIG. 19, the second electrode CE2 is omitted for the sake of convenience of explanation. FIG. 20 is a cross-sectional view taken along line XX-XX of FIG. 19.

Referring to FIGS. 19 and 20, for example, the sidewall diffusion layer 117a′ may be disposed across at least some of the pixels PX disposed in the same row. However, the embodiments of the present disclosure are not limited thereto. The sidewall diffusion layer 117a′ may be disposed on the passivation layer 116 in the display area AA. The sidewall diffusion layer 117a′ may be disposed around the bank BNK and the plurality of light-emitting elements ED. The sidewall diffusion layer 117a′ may cover the side surface and upper surface of the bank BNK and the side surfaces of the plurality of light-emitting elements ED.

The upper surface of the sidewall diffusion layer 117a′ may include a smooth and concave curved surface between the plurality of light-emitting elements ED. The sidewall diffusion layer 117a′ may include an organic insulating material having a plurality of fine particles dispersed therein.

The sidewall diffusion layer 117a′ may include a first sidewall diffusion layer 117a1 and a second sidewall diffusion layer 117a2 which are sequentially laminated on a third insulating layer 115c around the bank BNK and a plurality of light-emitting elements ED.

For example, the first sidewall diffusion layer 117a1 may be configured to surround the side surface and a portion of the upper surface of the bank BNK, and further surround the some side surfaces of the (2-1)-th light-emitting element 140a and the (2-2)-th light-emitting element 140b of the second light-emitting element 140, without being limited thereto. For example, the second sidewall diffusion layer 117a2 may be disposed on the first sidewall diffusion layer 117a1, without being limited thereto. As one example, the sidewall diffusion layer 117a′ may be configured to surround the bank BNK and the second light-emitting element 140 of the light-emitting elements ED.

As one example, the first sidewall diffusion layer 117a1 may include a different material than the second sidewall diffusion layer 117a2. For example, the first sidewall diffusion layer 117a1 and the second sidewall diffusion layer 117a2 may include different organic insulating materials.

The first sidewall diffusion layer 117a1 may include a first organic insulating material in which a plurality of first fine particles dispersed. The second sidewall diffusion layer 117a2 may include a second organic insulating material in which a plurality of second fine particles having a refractive index different from that of the first fine particles dispersed.

In this embodiment, the second sidewall diffusion layer 117a2 may be disposed on the first sidewall diffusion layer 117a1, and the refractive index of the plurality of second fine particles in the second sidewall diffusion layer 117a2 may be smaller than the refractive index of the plurality of first fine particles in the first sidewall diffusion layer 117a1, without being limited thereto. For example, the plurality of first fine particles may have a refractive index of 2.4 or greater, and the plurality of second fine particles may have a refractive index of less than 2.4. For example, the plurality of first fine particles may include titanium dioxide, and the plurality of second fine particles may include at least one of silicon dioxide, aluminum oxide, zinc oxide, and zirconium dioxide. Preferably, the plurality of second fine particles may include silicon dioxide having the lowest refractive index among silicon dioxide, aluminum oxide, zinc oxide and zirconium dioxide. However, the embodiments of the present disclosure are not limited thereto. For example, the plurality of second fine particles may include silicon dioxide and at least one of the aluminum oxide, zinc oxide, and zirconium dioxide. However, the embodiments of the present disclosure are not limited thereto. As an example, the plurality of second fine particles may include silicon dioxide and aluminum oxide. As an example, the plurality of second fine particles may include silicon dioxide and zinc oxide. As an example, the plurality of second fine particles may include silicon dioxide and zirconium dioxide. As an example, the plurality of second fine particles may include silicon dioxide, aluminum oxide, and zinc oxide. As an example, the plurality of second fine particles may include silicon dioxide, aluminum oxide, zinc oxide, and zirconium dioxide.

The number density of the plurality of second fine particles within the second sidewall diffusion layer 117a2 may be greater than the number density of the plurality of first fine particles within the first sidewall diffusion layer 117a1. However, the embodiments of the present disclosure are not limited thereto. Here, ‘number density’ means the number of fine particles per unit volume. Accordingly, the light scattering effect of the second sidewall diffusion layer 117a2 can be similar to or equivalent to the light scattering effect of the first sidewall diffusion layer 117a1.

The first organic insulating material included in the first sidewall diffusion layer 117a1 and the second organic insulating material included in the second sidewall diffusion layer 117a2 may be made of, for example, a siloxane resin. However, the embodiments of the present disclosure are not limited thereto.

In this embodiment, the first sidewall diffusion layer 117a1 may cover the side surface and upper surface of the bank BNK. And, the first sidewall diffusion layer 117a1 may cover the side surface and upper surface of the first electrode CE1 disposed on the bank BNK, and the side surface of the solder pattern SDP. Additionally, the first sidewall diffusion layer 117a1 may cover some side surfaces of the plurality of light-emitting elements ED. The first sidewall diffusion layer 117a1 may be in contact with some side surfaces of the plurality of light-emitting elements ED. The second sidewall diffusion layer 117a2 may be disposed directly on the upper surface of the first sidewall diffusion layer 117a1 to cover some remaining side surfaces of the plurality of light-emitting elements ED. The second sidewall diffusion layer 117a2 may be in contact with some remaining side surfaces of the plurality of light-emitting elements ED.

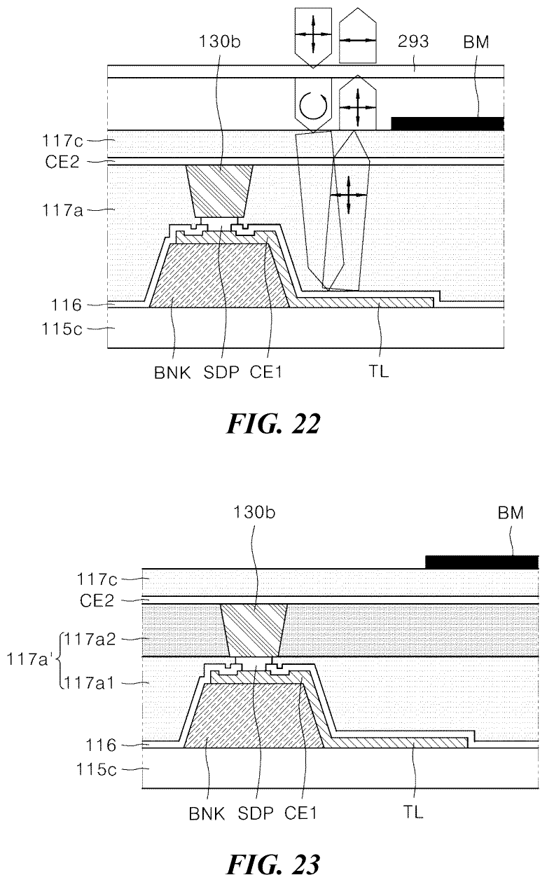

In the present embodiment, the second sidewall diffusion layer 117a2 of the sidewall diffusion layer 117a′ is disposed on the first sidewall diffusion layer 117a1 and includes a plurality of second fine particles having a refractive index lower than that of the plurality of first fine particles (e.g., titanium dioxide) included in the first sidewall diffusion layer 117a1, so that the non-polarized scattering characteristic of the sidewall diffusion layer 117a′ can be reduced and the external light reflection prevention characteristic of the display device 1000 can be improved, when compared to a case where the sidewall diffusion layer 117a is configured in a single-layer structure including the plurality of first fine particles (e.g., titanium dioxide). Detailed description regarding this will be provided later with reference to FIGS. 21 and 22.

And, according to the exemplary embodiment of the present disclosure, as the non-polarized scattering of the sidewall diffusion layer 117a′ is alleviated, the size of the opening of the black matrix BM can be increased, and thus, stain defects (e.g., stamp mura) caused by asymmetry and dispersion of the gap between the edge of the light-emitting element ED and the edge of the opening of the black matrix BM can be alleviated.

And, according to an exemplary embodiment of the present disclosure, light emitted from a plurality of light-emitting elements ED into the sidewall diffusion layer 117a′ can be scattered by the plurality of first fine particles and the plurality of second fine particles dispersed in the sidewall diffusion layer 117a′ and be emitted to the outside of the display device 1000. Accordingly, the sidewall diffusion layer 117a′ can improve the extraction efficiency of light emitted from a plurality of light-emitting elements ED. Additionally, the light extraction efficiency of the display device 1000 can be improved, thereby enabling the display device 1000 to be driven with low power.

Between neighboring sidewall diffusion layers 117a′ the window diffusion layer 117b may be disposed. The window diffusion layer 117b may be disposed on the passivation layer 116 in the display area AA. For example, the window diffusion layer 117b may be disposed on the passivation layer 116 between neighboring sidewall diffusion layers 117a′ in the display area AA. The window diffusion layer 117b may be disposed to surround the sidewall diffusion layer 117a′. For example, the window diffusion layer 117b may be in contact with the side surface of the sidewall diffusion layer 117a′. The upper surface of the window diffusion layer 117b may be higher than the upper surface of the sidewall diffusion layer 117a′.

The window diffusion layer 117b may be made of an organic insulating material. However, the embodiments of the present disclosure are not limited thereto. The window diffusion layer 117b may not include fine particles. For example, the window diffusion layer 117b may be made of a siloxane resin. However, the embodiments of the present disclosure are not limited thereto.

The sidewall diffusion layer 117a′, the window diffusion layer 117b, and the second electrode CE2 may be disposed on the plurality of light-emitting elements ED. For example, the second electrode CE2 may be electrically connected to the plurality of contact electrodes CCE through contact holes in the window diffusion layer 117b.

The second electrode CE2 may be continuously extended over the plurality of light-emitting elements ED, the sidewall diffusion layer 117a′, and the window diffusion layer 117b. In a case where the upper surface of the sidewall diffusion layer 117a′ is lower than the upper surface of the window diffusion layer 117b, the first portion of the second electrode CE2 disposed on the sidewall diffusion layer 117a′ may be disposed at a lower position than the second portion of the second electrode CE2 disposed on the window diffusion layer 117b.

An upper surface diffusion layer 117c may be disposed on the second electrode CE2. The upper surface diffusion layer 117c may be disposed to overlap the plurality of light-emitting elements ED and the sidewall diffusion layers 117a′.

The upper surface diffusion layer 117c may include a third organic insulating material in which a plurality of third fine particles dispersed. However, the embodiments of the present disclosure are not limited thereto. For example, the upper surface diffusion layer 117c may be made of the same material as the first sidewall diffusion layer 117a1. However, the embodiments of the present disclosure are not limited thereto. The plurality of third fine particles of the upper surface diffusion layer 117c may be made of the same material as the plurality of first fine particles of the first sidewall diffusion layer 117a1, and the third organic insulating material of the upper surface diffusion layer 117c may be made of the same material as the first organic insulating material of the first sidewall diffusion layer 117a1. However, the embodiments of the present disclosure are not limited thereto.

The upper surface diffusion layer 117c can evenly mix the lights emitted from the plurality of light-emitting elements ED to improve the luminance uniformity of the display device 1000.

The black matrix BM may be disposed on the second electrode CE2, the sidewall diffusion layer 117a′, the window diffusion layer 117b and the upper surface diffusion layer 117c in the display area AA. For example, the black matrix BM may fill the contact hole in the window diffusion layer 117b. The black matrix BM may include an opening exposing some of the plurality of light-emitting elements ED disposed on the bank BNK. The black matrix BM may cover a redundant light-emitting element 140b and expose the main light-emitting element 140a in one sub-pixel in a case where a main light-emitting element 140a operates normally. In a case where the main light-emitting element 140a is defective, the black matrix BM may cover the main light-emitting element 140a and expose the redundant light-emitting element 140b in one sub-pixel.

For example, the black matrix BM may be made of an opaque material. However, the embodiments of the present disclosure are not limited thereto. For example, the black matrix BM may be made of an organic insulating material having black pigment or black dye added thereto. However, the embodiments of the present disclosure are not limited thereto.

The polarizing layer 293 may be disposed on the display panel 100 to prevent or reduce external light reflection by components of the display panel 100. The polarizing layer 293 may be a circular polarizing layer including a linear polarizing layer and a λ/4 phase retardation layer. As external light passes through the linear polarization layer and the λ/4 phase retardation layer of the polarization layer 293 sequentially, it becomes circularly polarized and is incident on the display panel 100. Then, the light reflected by components within the display panel 100 and circularly polarized in the opposite direction is incident again on the polarization layer 293. As the light pass through the λ/4 phase retardation layer, it can be linearly polarized in a direction that intersects the transmission axis of the linear polarization layer by 90°, thus being blocked by the linear polarization layer.

FIG. 21 is a cross-sectional view taken along line XXI-XXI of FIG. 19. FIG. 22 is a cross-sectional view of a display device according to an exemplary embodiment of the present disclosure, corresponding to the cross-sectional view of FIG. 21.

First, in the embodiment of FIG. 22, the upper surface diffusion layer 117c and the sidewall diffusion layer 117a may include only a plurality of first fine particles made of titanium dioxide having a high refractive index. For example, both of the upper surface diffusion layer 117c and the sidewall diffusion layer 117a may include a plurality of first fine particles made of titanium dioxide having a high refractive index. The embodiment of FIG. 22 can improve the light extraction efficiency of the display device due to the excellent light scattering effect of the sidewall diffusion layer 117a. However, is disadvantageous in terms of preventing external light reflection.

A portion of light which has been circularly polarized light while passing through the polarizing layer 293 may be reflected by the light-emitting element ED or black matrix BM, and be circularly polarized in the opposite direction to be blocked by the polarizing layer 293.

However, a portion of circularly polarized light, which is incident on the region between the light-emitting element ED and the black matrix BM, may pass through the upper surface diffusion layer 117c and the sidewall diffusion layer 117a and be reflected by other components of the display panel 100. The reflected light is emitted through the sidewall diffusion layer 117a and the upper surface diffusion layer 117c, loses polarization due to unpolarized scattering by titanium dioxide particles with a high refractive index, and thus passing through the polarizing layer 293 to be recognized by the user.

As one example, a portion of the sidewall diffusion layer 117a′ may include a plurality of second fine particles having a lower refractive index. In the embodiment of FIG. 21, a portion of the sidewall diffusion layer 117a′, for example, the second sidewall diffusion layer 117a2, may include a plurality of second fine particles having a lower refractive index instead of a plurality of first fine particles made of titanium dioxide. Accordingly, in the process where a portion of the circularly polarized light, which is incident on an area between the light-emitting element ED and the black matrix BM, is reflected through the sidewall diffusion layer 117a′, unpolarized scattering by the plurality of first fine particles within the sidewall diffusion layer 117a′ can be reduced, thus the external light emitted through the polarizing layer 293 can be reduced.

FIG. 23 is a cross-sectional view of a display device according to an exemplary embodiment of the present disclosure. The embodiment of FIG. 23 will be discussed below mainly with regard to different features from FIGS. 20 and 21.

Referring to FIG. 23, the sidewall diffusion layer 117a′ may include a first sidewall diffusion layer 117a1 and a second sidewall diffusion layer 117a2 which are sequentially laminated on a third insulating layer 115c around the bank BNK and a plurality of light-emitting elements ED.

In this embodiment, the thickness of the first sidewall diffusion layer 117a1 may be decreased and the thickness of the second sidewall diffusion layer 117a2 may be increased, when compared to the embodiment of FIG. 21. The first sidewall diffusion layer 117a1 may cover the side surface and upper surface of the bank BNK. However, may not cover the side surfaces of the plurality of light-emitting elements ED. The first sidewall diffusion layer 117a1 may cover the side surface and upper surface of the first electrode CE1 disposed on the bank BNK, and the side surface of the solder pattern SDP. The second sidewall diffusion layer 117a2 may be positioned directly on the upper surface of the first sidewall diffusion layer 117a1, and the second sidewall diffusion layer 117a2 may cover the entire side surfaces of the plurality of light-emitting elements ED. The second sidewall diffusion layer 117a2 may be in contact with the entire side surfaces of the plurality of light-emitting elements ED.

As one example, the sidewall diffusion layer 117a′ may include the first sidewall diffusion layer 117a1 and the second sidewall diffusion layer 117a2, the first sidewall diffusion layer 117a1 may include a plurality of first fine particles (e.g., titanium dioxide), and the second sidewall diffusion layer 117a2 may include a plurality of second fine particles having a refractive index different from a refractive index of the plurality of first fine particles.

In the present embodiment, the second sidewall diffusion layer 117a2 of the sidewall diffusion layer 117a′ is disposed on the first sidewall diffusion layer 117a1 and includes a plurality of second fine particles having a refractive index lower than that of the plurality of first fine particles (e.g., titanium dioxide) included in the first sidewall diffusion layer 117a1, so that the non-polarized scattering characteristic of the sidewall diffusion layer 117a′ can be reduced and the external light reflection prevention characteristic of the display device 1000 can be improved, when compared to a case where the sidewall diffusion layer 117a is configured in a single-layer structure including the plurality of first fine particles (e.g., titanium dioxide).

And, according to the exemplary embodiment of the present disclosure, as the non-polarized scattering of the sidewall diffusion layer 117a′ is alleviated, the size of the opening of the black matrix BM can be increased, and thus, stain defects (e.g., stamp mura) caused by asymmetry and dispersion of the gap between the edge of the light-emitting element ED and the edge of the opening of the black matrix BM can be alleviated.

In the embodiment of FIG. 23, the second sidewall diffusion layer 117a2 may be in contact with the entire side surfaces of the plurality of light-emitting elements ED, but is not limited thereto. In another embodiment, the second sidewall diffusion layer 117a2 may cover not only the entire side surfaces of the plurality of light-emitting elements ED, but also the side surfaces of the plurality of solder patterns SDP disposed between the plurality of first electrodes CE1 and the plurality of light-emitting elements ED. The second sidewall diffusion layer 117a2 may be in contact with the entire side surfaces of the plurality of light-emitting elements ED and the solder pattern SDP.

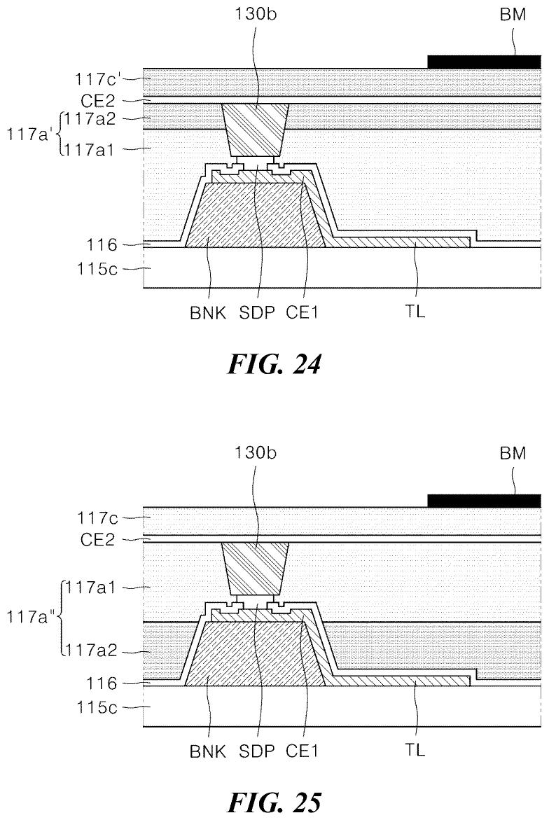

FIG. 24 is a cross-sectional view of a display device according to an exemplary embodiment of the present disclosure. The embodiment of FIG. 24 will be discussed below mainly with regard to different features from FIGS. 20 and 21.

Referring to FIG. 24, the sidewall diffusion layer 117a′ may include a first sidewall diffusion layer 117a1 and a second sidewall diffusion layer 117a2 which are sequentially laminated on a third insulating layer 115c around the bank BNK and a plurality of light-emitting elements ED. The second sidewall diffusion layer 117a2 may be positioned directly on the upper surface of the first sidewall diffusion layer 117a1, and the second sidewall diffusion layer 117a2 may cover portions of the side surfaces of the plurality of light-emitting elements ED, but is not limited thereto. In one embodiment, the second sidewall diffusion layer 117a2 may cover the entire side surfaces of the plurality of light-emitting elements ED. In this embodiment, unlike the embodiment of FIG. 21, the upper surface diffusion layer 117c′ may be made of the same material as the second sidewall diffusion layer 117a2. A plurality of third fine particles of the upper surface diffusion layer 117c′ may be made of the same material as a plurality of second fine particles of the second sidewall diffusion layer 117a2. The plurality of third fine particles of the upper surface diffusion layer 117c′ may have a refractive index lower than that of the plurality of first fine particles of the first sidewall diffusion layer 117a1.

As one example, the sidewall diffusion layer 117a′ may include the first sidewall diffusion layer 117a1 and the second sidewall diffusion layer 117a2, the first sidewall diffusion layer 117a1 may include the plurality of first fine particles, and the second sidewall diffusion layer 117a2 may include a plurality of second fine particles having a refractive index different from a refractive index of the plurality of first fine particles.

In the present embodiment, the second sidewall diffusion layer 117a2 of the sidewall diffusion layer 117a′ and upper surface diffusion layer 117c′ include the plurality of second fine particles having a refractive index lower than that of the plurality of first fine particles (e.g., titanium dioxide) included in the first sidewall diffusion layer 117a1, so that the external light reflection prevention characteristic of the display device 1000 can be improved, when compared to a case where the sidewall diffusion layer 117a is configured in a single-layer structure including the plurality of first fine particles (e.g., titanium dioxide) and the upper surface diffusion layer 117c includes a plurality of third fine particles made of the same material as the plurality of first fine particles.

And, according to the exemplary embodiment of the present disclosure, as the non-polarized scattering of the sidewall diffusion layer 117a′ is alleviated, the size of the opening of the black matrix BM can be increased, and thus, stain defects (e.g., stamp mura) caused by asymmetry and dispersion of the gap between the edge of the light-emitting element ED and the edge of the opening of the black matrix BM can be alleviated.

FIG. 25 is a cross-sectional view of a display device according to an exemplary embodiment of the present disclosure. The embodiment of FIG. 25 will be discussed below mainly with regard to different features from FIGS. 20 and 21.

Referring to FIG. 25, the sidewall diffusion layer 117a″ may include a second sidewall diffusion layer 117a2 and a first sidewall diffusion layer 117a1 which are sequentially laminated on a third insulating layer 115c around the bank BNK and a plurality of light-emitting elements ED. The second sidewall diffusion layer 117a2 may be positioned below the first sidewall diffusion layer 117a1, and the first sidewall diffusion layer 117a1 may cover the entire side surfaces of the plurality of light-emitting elements ED. The first sidewall diffusion layer 117a1 may be in contact with the entire side surfaces of the plurality of light-emitting elements ED. For example, the first sidewall diffusion layer 117a1 may further cover the side surfaces of the solder pattern SDP and a portion of the side surfaces of the passivation layer 116.

The second sidewall diffusion layer 117a2 may cover the entire side surface of the bank BNK. However, embodiments of the present disclosure are not limited thereto. The second sidewall diffusion layer 117a2 may cover a portion of the side surface of the bank BNK, or may cover the entire side surface and upper surface of the bank BNK. In one embodiment, the second sidewall diffusion layer 117a2 may cover the entire side surface and upper surface of the bank BNK, as well as the side surface of the solder pattern SDP.

As one example, the sidewall diffusion layer 117a″ may include the first sidewall diffusion layer 117a1 and the second sidewall diffusion layer 117a2, the first sidewall diffusion layer 117a1 may include the plurality of first fine particles, and the second sidewall diffusion layer 117a2 may include a plurality of second fine particles having a refractive index different from a refractive index of the plurality of first fine particles.

In the present embodiment, the second sidewall diffusion layer 117a2 of the sidewall diffusion layer 117a″ is disposed below the first sidewall diffusion layer 117a1 and includes a plurality of second fine particles having a refractive index lower than that of the plurality of first fine particles (e.g., titanium dioxide) included in the first sidewall diffusion layer 117a1, so that the external light reflection prevention characteristic of the display device 1000 can be improved, when compared to a case where the sidewall diffusion layer 117a is configured in a single-layer structure including the plurality of first fine particles (e.g., titanium dioxide).

And, according to the exemplary embodiment of the present disclosure, as the non-polarized scattering of the sidewall diffusion layer 117a″ is alleviated, the size of the opening of the black matrix BM can be increased, and thus, stain defects (e.g., stamp mura) caused by asymmetry and dispersion of the gap between the edge of the light-emitting element ED and the edge of the opening of the black matrix BM can be alleviated.

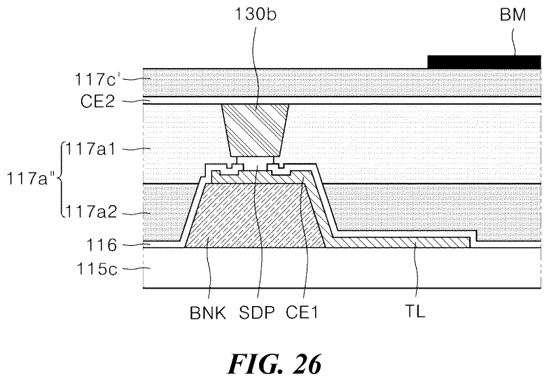

FIG. 26 is a cross-sectional view of a display device according to an exemplary embodiment of the present disclosure. The embodiment of FIG. 26 will be discussed below mainly with regard to different features from FIGS. 20 and 21.

Referring to FIG. 26, the sidewall diffusion layer 117a″ may include a second sidewall diffusion layer 117a2 and a first sidewall diffusion layer 117a1 which are sequentially laminated on a third insulating layer 115c around the bank BNK and a plurality of light-emitting elements ED. The second sidewall diffusion layer 117a2 may be positioned below the first sidewall diffusion layer 117a1, and the first sidewall diffusion layer 117a1 may cover the entire side surfaces of the plurality of light-emitting elements ED. The first sidewall diffusion layer 117a1 may be in contact with the entire side surfaces of the plurality of light-emitting elements ED.

The second sidewall diffusion layer 117a2 may cover the entire side surface of the bank BNK. However, embodiments of the present disclosure are not limited thereto. The second sidewall diffusion layer 117a2 may cover a portion of the side surface of the bank BNK, or may cover the entire side surface and upper surface of the bank BNK. In one embodiment, the second sidewall diffusion layer 117a2 may cover the entire side surface and upper surface of the bank BNK, as well as the side surface of the solder pattern SDP.

In this embodiment, unlike the embodiment of FIG. 21, the upper surface diffusion layer 117c′ may be made of the same material as the second sidewall diffusion layer 117a2. A plurality of third fine particles of the upper surface diffusion layer 117c′ may be made of the same material as a plurality of second fine particles of the second sidewall diffusion layer 117a2. The plurality of third fine particles of the upper surface diffusion layer 117c′ may have a refractive index lower than that of the plurality of first fine particles of the first sidewall diffusion layer 117a1.

As one example, the sidewall diffusion layer 117a″ may include the first sidewall diffusion layer 117a1 and the second sidewall diffusion layer 117a2, the first sidewall diffusion layer 117a1 may include the plurality of first fine particles, and the second sidewall diffusion layer 117a2 may include a plurality of second fine particles having a refractive index different from a refractive index of the plurality of first fine particles.

In the present embodiment, the second sidewall diffusion layer 117a2 of the sidewall diffusion layer 117a″ and upper surface diffusion layer 117c′ include the plurality of second fine particles having a refractive index lower than that of the plurality of first fine particles (e.g., titanium dioxide) included in the first sidewall diffusion layer 117a1, so that the external light reflection prevention characteristic of the display device 1000 can be improved, when compared to a case where the sidewall diffusion layer 117a is configured in a single-layer structure including the plurality of first fine particles (e.g., titanium dioxide) and the upper surface diffusion layer 117c includes a plurality of third fine particles made of the same material as the plurality of first fine particles.

And, according to the exemplary embodiment of the present disclosure, as the non-polarized scattering of the sidewall diffusion layer 117a″ is alleviated, the size of the opening of the black matrix BM can be increased, and thus, stain defects (e.g., stamp mura) caused by asymmetry and dispersion of the gap between the edge of the light-emitting element ED and the edge of the opening of the black matrix BM can be alleviated.

In some embodiments, the first sidewall diffusion layer 117a1 and the second sidewall diffusion layer 117a2 may together form a refractive index gradient structure around the light-emitting element ED. The first sidewall diffusion layer may 117a1 include a plurality of first fine particles having a first refractive index, and the second sidewall diffusion layer may include a plurality of second fine particles having a second refractive index different from the first refractive index. For example, the first fine particles may be made of titanium dioxide, which has a relatively high refractive index, and the second fine particles may be made of silicon dioxide, aluminum oxide, or other materials with lower refractive indices. By sequentially laminating these layers with different refractive indices, the interface between the layers can create a stepwise refractive index profile in the lateral direction surrounding the light-emitting element ED. This refractive index gradient structure can improve the light extraction efficiency by promoting more efficient redirection and transmission of light emitted from the light-emitting element, while simultaneously reducing unwanted reflections and non-polarized scattering at the interfaces.

The display device according to various embodiments of the present disclosure may be described as follows.

A display device according to various embodiments of the present disclosure may include a substrate, at least one driving chip disposed on the substrate, a bank disposed on the driving chip, a first electrode disposed on the bank and electrically connected to the at least one driving chip, a light-emitting element disposed on the first electrode, and first and second sidewall diffusion layers laminated around the bank and the light-emitting element, wherein the first sidewall diffusion layer may include a plurality of first fine particles, and the second sidewall diffusion layer may include a plurality of second fine particles having a refractive index different from that of the plurality of first fine particles.

According to various embodiments of the present disclosure, the second sidewall diffusion layer may be disposed on the first sidewall diffusion layer, and the refractive index of the plurality of second fine particles may be lower than the refractive index of the plurality of first fine particles.

According to various embodiments of the present disclosure, a number density of the plurality of second fine particles within the second sidewall diffusion layer may be greater than a number density of the plurality of first fine particles within the first sidewall diffusion layer.

According to various embodiments of the present disclosure, the plurality of first fine particles included in the first sidewall diffusion layer may include titanium dioxide, and the plurality of second fine particles included in the second sidewall diffusion layer may include at least one of silicon dioxide, aluminum oxide, zinc oxide, or zirconium dioxide.

According to various embodiments of the present disclosure, the second sidewall diffusion layer may be in contact with a portion of a side surface of the light-emitting element.

According to various embodiments of the present disclosure, the second sidewall diffusion layer may be in contact with an entire side surface of the light-emitting element.

According to various embodiments of the present disclosure, the display device may further include a solder pattern disposed between the first electrode and the light-emitting element, wherein the second sidewall diffusion layer may be in contact with an entire side surface of the light-emitting element and the solder pattern.

According to various embodiments of the present disclosure, the second sidewall diffusion layer may be disposed below the first sidewall diffusion layer, and a refractive index of the plurality of second fine particles may be less than a refractive index of the plurality of first fine particles.

According to various embodiments of the present disclosure, the plurality of first fine particles included in the first sidewall diffusion layer may include titanium dioxide, and the plurality of second fine particles included in the second sidewall diffusion layer may include at least one of silicon dioxide, aluminum oxide, zinc oxide, or zirconium dioxide.

According to various embodiments of the present disclosure, the first sidewall diffusion layer may be in contact with an entire side surface of the light-emitting element.

According to various embodiments of the present disclosure, the second sidewall diffusion layer may be in contact with an entire side surface of the bank.

According to various embodiments of the present disclosure, the display device may include a second electrode disposed on the light-emitting element and on the first sidewall diffusion layer or the second sidewall diffusion layer, and an upper side diffusion layer disposed on the second electrode, wherein the upper side diffusion layer may include a plurality of third fine particles having a refractive index different from that of the plurality of first fine particles.

According to various embodiments of the present disclosure, the plurality of third fine particles may be made of the same material as the plurality of second fine particles.

According to various embodiments of the present disclosure, a refractive index of the plurality of third fine particles may be lower than a refractive index of the plurality of first fine particles.

According to various embodiments of the present disclosure, the second sidewall diffusion layer may be disposed on the first sidewall diffusion layer, and a refractive index of the plurality of second fine particles may be lower than a refractive index of the plurality of first fine particles.

According to various embodiments of the present disclosure, the light-emitting element may be a micro LED.

A display device according to various embodiments of the present disclosure may include a substrate, at least one light-emitting element disposed on the substrate, a sidewall diffusion layer covering a side surface of the at least one light-emitting element, and a transparent electrode disposed on the at least one light-emitting element and the sidewall diffusion layer, wherein the sidewall diffusion layer may include a first sidewall diffusion layer having a plurality of first fine particles dispersed therein and a second sidewall diffusion layer having a plurality of second fine particles dispersed therein, and the plurality of first fine particles and the plurality of second fine particles may have refractive indices different from each other.

According to various embodiments of the present disclosure, the plurality of first fine particles may include titanium dioxide, and the plurality of second fine particles may include at least one of silicon dioxide, aluminum oxide, zinc oxide, or zirconium dioxide.

According to various embodiments of the present disclosure, the display device may include an upper side diffusion layer disposed on the transparent electrode, wherein the upper side diffusion layer may include a plurality of third fine particles having a refractive index different from that of the plurality of first fine particles.

According to various embodiments of the present disclosure, the plurality of third fine particles may include at least one of silicon dioxide, aluminum oxide, zinc oxide, or zirconium dioxide.

A display device according to various embodiments of the present disclosure may include a driving chip comprising a plurality of driving circuits to drive at least one of a plurality of light-emitting elements; a bank disposed on the driving chip; first and second sidewall diffusion layers laminated around the bank and the light-emitting element, in which the first sidewall diffusion layer includes a plurality of first fine particles, and a refractive index of a plurality of second fine particles included in the second sidewall diffusion layer is lower than a refractive index of the plurality of first fine particles.

While the embodiments of the present disclosure have been described in detail with reference to the accompanying drawings, it should be understood by a person skilled in the art that the present disclosure is not necessarily limited to the above embodiments, and the above embodiments can be modified without departing from the technical idea of the present disclosure. Accordingly, the embodiments disclosed in the present disclosure are not intended to limit the technical idea of the present disclosure but to explain the technical idea of the present disclosure, and the scope of the technical idea of the present disclosure is not limited by the above embodiments. Therefore, it should be understood that the embodiments described above are given only as an example in all respects but not for a limiting purpose.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate;
at least one driving chip on the substrate;
a bank on the at least one driving chip;
a first electrode on the bank and electrically connected to the at least one driving chip;
a light-emitting element on the first electrode; and
first and second sidewall diffusion layers laminated around the bank and the light-emitting element,
wherein the first sidewall diffusion layer includes a plurality of first fine particles, and the second sidewall diffusion layer includes a plurality of second fine particles having a refractive index different from a refractive index of the plurality of first fine particles.

2. The display device of claim 1, wherein the second sidewall diffusion layer is on the first sidewall diffusion layer, and
wherein the refractive index of the plurality of second fine particles is lower than the refractive index of the plurality of first fine particles.

3. The display device of claim 2, wherein a number density of the plurality of second fine particles within the second sidewall diffusion layer is greater than a number density of the plurality of first fine particles within the first sidewall diffusion layer.

4. The display device of claim 1, wherein the plurality of first fine particles included in the first sidewall diffusion layer includes titanium dioxide, and the plurality of second fine particles included in the second sidewall diffusion layer includes at least one of silicon dioxide, aluminum oxide, zinc oxide, or zirconium dioxide.

5. The display device of claim 1, wherein the second sidewall diffusion layer is in contact with a portion of a side surface of the light-emitting element.

6. The display device of claim 1, wherein the second sidewall diffusion layer is in contact with an entire side surface of the light-emitting element.

7. The display device of claim 1, further comprising:
a solder pattern between the first electrode and the light-emitting element,
wherein the second sidewall diffusion layer is in contact with an entire side surface of the light-emitting element and the solder pattern.

8. The display device of claim 1, wherein the second sidewall diffusion layer is disposed below the first sidewall diffusion layer, and
wherein the refractive index of the plurality of second fine particles is lower than the refractive index of the plurality of first fine particles.

9. The display device of claim 8, wherein the plurality of first fine particles included in the first sidewall diffusion layer includes titanium dioxide, and
wherein the plurality of second fine particles included in the second sidewall diffusion layer includes at least one of silicon dioxide, aluminum oxide, zinc oxide, or zirconium dioxide.

10. The display device of claim 8, wherein the first sidewall diffusion layer is in contact with an entire side surface of the light-emitting element.

11. The display device of claim 10, wherein the second sidewall diffusion layer is in contact with an entire side surface of the bank.

12. The display device of claim 1, further comprising:
a second electrode on the light-emitting element and on the first sidewall diffusion layer or the second sidewall diffusion layer; and
an upper side diffusion layer on the second electrode,
wherein the upper side diffusion layer includes a plurality of third fine particles having a refractive index different from the refractive index of the plurality of first fine particles.

13. The display device of claim 12, wherein the plurality of third fine particles is made of a same material as the plurality of second fine particles.

14. The display device of claim 12, wherein a refractive index of the plurality of third fine particles is lower than a refractive index of the plurality of first fine particles.

15. The display device of claim 13, wherein the second sidewall diffusion layer is on the first sidewall diffusion layer, and
wherein a refractive index of the plurality of second fine particles is lower than a refractive index of the plurality of first fine particles.

16. The display device of claim 1, wherein the light-emitting element includes a micro LED.

17. A display device comprising:
a substrate;
at least one light-emitting element on the substrate;
a sidewall diffusion layer covering a side surface of the at least one light-emitting element and having a plurality of fine particles dispersed therein; and
a transparent electrode on the at least one light-emitting element and the sidewall diffusion layer.

18. The display device of claim 17, wherein the sidewall diffusion layer includes a first sidewall diffusion layer having a plurality of first fine particles dispersed therein and a second sidewall diffusion layer having a plurality of second fine particles dispersed therein, and the plurality of first fine particles and the plurality of second fine particles have refractive indices different from each other.

19. The display device of claim 18, wherein the plurality of first fine particles includes titanium dioxide, and the plurality of second fine particles includes at least one of silicon dioxide, aluminum oxide, zinc oxide, or zirconium dioxide.

20. The display device of claim 18, further comprising:
an upper side diffusion layer on the transparent electrode,
wherein the upper side diffusion layer includes a plurality of third fine particles having a refractive index different from the refractive index of the plurality of first fine particles.

21. The display device of claim 20, wherein the plurality of third fine particles includes at least one of silicon dioxide, aluminum oxide, zinc oxide, or zirconium dioxide.

22. A display device comprising:
a driving chip comprising a plurality of driving circuits to drive at least one of a plurality of light-emitting elements;
a bank on the driving chip;
first and second sidewall diffusion layers laminated around the bank and a light-emitting element among the at least one of a plurality of light-emitting elements,
wherein the first sidewall diffusion layer includes a plurality of first fine particles and the second sidewall diffusion layer includes a plurality of second fine particles, and a refractive index of a plurality of second fine particles is lower than a refractive index of the plurality of first fine particles.

23. The display device of claim 22, wherein the first and second sidewall diffusion layers together form a refractive index gradient structure around the light-emitting element.
